(19) United States
(12) Patent Application Publication
(10) Pub. No.: US 2016/0233448 A1
(43) Pub. Date: Aug. 11, 2016

(54) MULTIPLE DONOR/ACCEPTOR BULK HETEROJUNCTION SOLAR CELLS

(71) Applicant: THE REGENTS OF THE UNIVERSITY OF CALIFORNIA, Oakland, CA (US)

(72) Inventors: Yang Yang, Los Angeles, CA (US); Yang M. Yang, Los Angeles, CA (US); Gang Li, Arcadia, CA (US)

(73) Assignee: The Regents of the University of California, Oakland, CA (US)

(21) Appl. No.: 15/023,072

(22) PCT Filed: Sep. 23, 2014
(86) PCT No.: PCT/US2014/057062

§ 371 Date: Mar. 18, 2016

Related U.S. Application Data
(60) Provisional application No. 61/881,265, filed on Sep. 23, 2013.

(51) Int. Cl. H01L 51/42

(52) U.S. Cl. CPC H01L 51/4253; H01L 51/0036

(57) ABSTRACT

An organic photovoltaic device includes a first electrode, a second electrode proximate the first electrode with a space reserved therebetween, and a bulk heterojunction active layer arranged between and in electrical connection with the first and second electrodes. The bulk heterojunction active layer comprises a blend of at least one of a plurality of organic electron donor materials and a plurality of electron acceptor materials. The plurality of organic electron donor materials have different photon absorption characteristics so as to provide an enhanced photon absorption bandwidth, and at least one of the plurality of organic electron donor materials and plurality of electron acceptor materials are structurally compatible so as to provide enhanced operation.

This application claims priority to U.S. Provisional Application No. 61/881,265 filed Sep. 23, 2013, the entire content of which is hereby incorporated by reference.

This invention was made with Government support under Grant No. N00014-11-1-0250, awarded by the U.S. Navy, Office of Naval Research. The Government has certain rights in this invention.

### BACKGROUND

1. Technical Field

The field of the currently claimed embodiments of this invention relates to solar cells, and more particularly to multiple donor/acceptor bulk heterojunction solar cells.

2. Discussion of Related Art

All references cited anywhere in this specification are hereby incorporated by reference herein.

Polymer photovoltaic cells have shown great potential as a means to harvest solar energy in a highly processable and cost-effective manner¹⁻⁵. Typical polymer solar cells consist of a mixture of a polymer (or organic small molecule) donor and C-60 derivative acceptor as the photo-active layer. In bulk-heterojunction (BHJ) organic solar cells, the absorbed incident photons generate tightly bound electron-hole pairs, which are then dissociated into electrons and holes at the nearby donor/acceptor interface. The electrons and holes are then transported to their respective electrodes⁶⁻⁸.

Research efforts in the last decade or so have significantly improved organic solar cell performance⁹⁻¹⁴, and power conversion efficiency (PCE) values beyond 10% have recently been achieved¹⁵⁻¹⁶. Over the years, significant research efforts have been put into developing low band gap polymers to extend the absorption and harvest more solar energy. Nevertheless, unlike the continuous band structure of inorganic semiconductors like Si, the molecular orbital energy level of organic semiconductors is narrow, which makes it challenging to obtain the panchromatic absorption coverage with a single organic semiconductor. This is one of the reasons that polymer solar cells invariably exhibit low short circuit current (Jsc), compared with commercial inorganic solar cells. In addition, it has been very difficult to achieve as high an external quantum efficiency (EQE) in low band gap polymer systems (Eg<1.4 eV) as in traditional polymer systems such as poly(3-hexyl thiophene) (P3HT) with reported EQE values of over 70%¹⁷. Therefore, there remains a need for improved bulk heterojunction solar cells.

### SUMMARY

According to some embodiments of the present invention, an organic photovoltaic device includes a first electrode, a second electrode proximate the first electrode with a space reserved therebetween, and a bulk heterojunction active layer arranged between and in electrical connection with the first and second electrodes. The bulk heterojunction active layer comprises a blend of at least one of a plurality of organic electron donor materials and a plurality of electron acceptor materials. The plurality of organic electron donor materials have different photon absorption characteristics so as to provide an enhanced photon absorption bandwidth, and at least one of the plurality of organic electron donor materials and plurality of electron acceptor materials are structurally compatible so as to provide enhanced operation.

According to some embodiments of the present invention, a method of producing a composition for a bulk heterojunction active layer of an organic photovoltaic device includes selecting a first organic electron donor material, selecting a first electron acceptor material, and selecting at least one of a second organic electron donor material that is structurally compatible with the first organic electron donor material or a second electron acceptor material that is structurally compatible with the first electron acceptor material. The method further includes blending all materials selected to provide the composition.

### BRIEF DESCRIPTION OF THE DRAWINGS

Further objectives and advantages will become apparent from a consideration of the description, drawings, and examples.

FIG. 1 is a schematic illustration of an organic photovoltaic device according to an embodiment of the invention;

FIG. 2A shows a schematic illustration of chemical structures of materials used according to an embodiment of the invention;

FIG. 2B shows absorption spectra of materials used according to an embodiment of the invention;

FIG. 2C shows energy band diagrams of the material pool according to an embodiment of the invention;

FIG. 2D shows a schematic illustration of chemical structures of donor materials used according to an embodiment of the invention;

FIG. 2E shows a schematic illustration of chemical structures of acceptor materials used according to an embodiment of the invention;

FIG. 2F shows a schematic illustration of chemical structures of additional acceptor materials used according to an embodiment of the invention;

FIG. 3A shows a current-voltage (J-V) curve of the (P3HT:PBDTT-DPP):PC₇₀BM ternary BHJ solar cell system measured under one sun conditions (100 mW/cm²);

FIG. 3B shows an external quantum efficiency (EQE) measurement of the (P3HT:PBDTT-DPP):PC₇₀BM ternary BHJ solar cell system;

FIG. 3C shows a J-V curve of the (PBDTTT-C:PBDTT-DPP):PC₇₀BM ternary BHJ solar cell system measured under one sun conditions (100 mW/cm²);

FIG. 3D shows an EQE measurement of the (PBDTTT-C:PBDTT-DPP):PC₇₀BM ternary BHJ solar cell system;

FIG. 4 displays a table showing device performance of the (PDBTTT-C:PBDTT-DPP):PC70BM, (P3HT:PBDTT-DPP):PC70BM, and (P3HT:PBDTTT-C):PC70BM ternary systems;

FIG. 5 is a schematic illustration of the molecular interactions in the polymer blends of (PBDTTT-C:PBDTT-DPP) and (P3HT:PBDTT-DPP);

FIG. 6A shows J-V characteristics of the (PTB7:PBDTT-SeDPP):PC70BM ternary BHJ solar cell system measured under one sun conditions (100 mW/cm2);

FIG. 6B shows EQE measurement of the (PTB7:PBDTT-SeDPP):PC70BM ternary BHJ solar cell system;

FIG. 6C shows J-V characteristics of the PDBTTT-C:PBDTT-DPP:PTB7:PBDTT-SeDPP):PC70BM multi-donor BHJ solar cell system, measured under one sun conditions (100 mW/cm2);

FIG. 6D shows EQE measurement of the (PDBTTT-C:PBDTT-DPP:PTB7:PBDTT-SeDPP):PC70BM multi-donor BHJ system;

FIG. 7 displays a table showing device performance of the (PTB7:PBDTT-SeDPP):PC70BM and (PBDTTT-C:PBDTT-DPP:PTB7:PBDTT-SeDPP):PC70BM multiple donor BHJ systems;

FIG. 8A shows the absorption spectrum for (P3HT:PBDTT-DPP) dual donor polymer blends;

FIG. 8B shows the absorption spectrum for (PBDTTT-C:PBDTT-DPP) dual donor polymer blends;

FIG. 9 displays a table showing device performance of the (P3HT:PBDTT-DPP):PC70BM, (P3HT:PBDTTT-C):PC70BM, (P3HT:PTB7):PC70BM and (P3HT:PBDTT-SeDPP):PC70BM solar cell ternary systems;

FIG. 10A is a schematic illustration of the experimental setup of photo-charge extraction by linearly increasing voltage (CELIV) measurement according to an embodiment of the invention;

FIG. 10B shows photo-CELIV transients of (PBDTTT-C:PBDTT-DPP):PC70BM ternary and its reference binary systems;

FIG. 10C shows photo-CELIV transients of (P3HT:PBDTT-DPP):PC70BM ternary and its reference binary systems;

FIG. 10D shows photo-CELIV transients of a (PBDTTT-C:PBDTT-DPP):PC70BM ternary BHJ device, as a function of different extracting voltages;

FIG. 10E shows photo-CELIV transients of a (P3HT:PBDTT-DPP):PC70BM ternary BHJ device, as a function of different extracting voltages;

FIG. 11 shows grazing incidence wide angle X-ray scattering (GIWAXS) patterns for single polymer films of PBDTTT-C, PBDTT-DPP, and P3HT, and polymer blends of (PBDTTT-C:PBDTT-DPP) and (P3HT:PBDTT-DPP);

FIG. 12A displays a table showing quantitative information about molecular orientation and crystallinity in (PDBTTT-C:PBDTT-DPP) and (P3HT:PBDTT-DPP) blends, extracted from the 2D-GIWAXRS patterns;

FIG. 12B displays a table summarizing the quantitative molecular packing information for (PDBTTT-C:PBDTT-DPP) and (P3HT:PBDTT-DPP) blends extracted from the 2D-GIWAXRS patterns in the (100) direction;

FIG. 13 shows a plot of a photo-CELIV measurement of the (PTB7:PBDTT-DPP):PC₇₀BM ternary BHJ solar cell system;

FIG. 14A shows a general schematic of band structure of organic/polymeric and inorganic semiconductors;

FIG. 14B shows absorption spectra of the material pool according to an embodiment of the invention;

FIG. 14C shows energy band diagrams of the material pool according to an embodiment of the invention;

FIG. 15A shows a J-V curve of the (P3HT:PBDTT-DPP):PC70BM ternary BHJ solar cell system measured under one sun conditions (100 mW/cm²);

FIG. 15B shows an EQE measurement of the (P3HT:PBDTT-DPP):PC70BM ternary BHJ solar cell system;

FIG. 15C shows a J-V curve of the (P3HT:PBDTT-SeDPP):PC70BM ternary BHJ solar cell system measured under one sun conditions (100 mW/cm²);

FIG. 15D shows an EQE measurement of the (P3HT:PBDTT-SeDPP):PC70BM ternary BHJ solar cell system;

FIG. 16 displays a table showing device performance of (P3HT:PBDTT-DPP):PC70BM, and (P3HT:PBDTT-SeDPP):PC70BM BHJ ternary solar cell systems;

FIG. 17A shows a J-V curve of the (PBDTTT-C:PBDTT-DPP):PC70BM ternary BHJ solar cell system measured under one sun conditions (100 mW/cm²);

FIG. 17B shows an EQE measurement of the (PBDTTT-C:PBDTT-DPP):PC70BM ternary BHJ solar cell system;

FIG. 17C shows a J-V curve of the (PTB7:PBDTT-SeDPP):PC70BM ternary BHJ solar cell system measured under one sun conditions (100 mW/cm²);

FIG. 17D shows an EQE measurement of the (PTB7:PBDTT-SeDPP):PC70BM ternary BHJ solar cell system;

FIG. 17E shows a J-V curve of (PBDTTT-C:PBDTT-DPP:PTB7:PBDTT-SeDPP):PC70BM multi-donor BHJ measured under one sun (100 mW/cm²) and dark conditions;

FIG. 17F shows an EQE measurement of the multi-donor system;

FIG. 18 displays a table showing device performance of the (PDBTTT-C:PBDTT-DPP):PC70BM ternary BHJ solar cell system;

FIG. 19 displays a table showing device performance of the (PTB7:PBDTT-SeDPP):PC70BM ternary BHJ solar cell system;

FIG. 20A shows a J-V curve of the (PBDTTT-C:PBDTT-SeDPP):PC70BM ternary BHJ solar cell system measured under one sun conditions (100 mW/cm2);

FIG. 20B shows an EQE measurement of the (PBDTTT-C:PBDTT-SeDPP):PC70BM ternary BHJ solar cell system;

FIG. 21 displays a table showing the device performance of (PBDTTT-C:PBDTT-SeDPP):PC70BM BHJ ternary solar cell systems;

FIG. 22A shows a J-V curve of the (PTB7:PBDTT-DPP):PC₇₀BM ternary BHJ solar cell system measured under one sun conditions (100 mW/cm²);

FIG. 22B shows an EQE measurement of the (PTB7:PBDTT-DPP):PC₇₀BM ternary BHJ solar cell system;

FIG. 23 displays a table showing device performance of (PTB7:PBDTT-DPP):PC70BM BHJ ternary solar cell systems;

FIG. 24A shows photo-CELIV transients of PBDTTT-C:PC₇₀BM with different applied electric fields;

FIG. 24B shows photo-CELIV transients of PBDTT-DPP:PC₇₀BM with different applied electric fields;

FIG. 24C shows photo-CELIV transients of (PBDTTT-C:PBDTT-DPP):PC₇₀BM with different applied electric fields;

FIG. 24D shows photo-CELIV transients of PTB7:PC₇₀BM with different applied electric fields;

FIG. 24E shows photo-CELIV transients of PBDTT-SeDPP:PC₇₀BM with different applied electric fields;

FIG. 24F (PTB7:PBDTT-SeDPP):PC₇₀BM with different applied electric fields;

FIG. 25A shows photo-CELIV transients of P3HT:PC70BM with different applied electric fields;

FIG. 25B shows photo-CELIV transients of PBDTT-DPP:PC70BM with different applied electric fields;

FIG. 25C shows photo-CELIV transients of (P3HT:PBDTT-DPP):PC70BM with different applied electric fields;

FIG. 25D shows photo-CELIV transients of PBDTT-SeDPP:PC70BM with different applied electric fields;

FIG. 25E shows photo-CELIV transients of (P3HT:PBDTT-SeDPP):PC70BM with different applied electric fields;

FIG. 25F shows electric field dependent charge carrier mobility of the compatible and incompatible ternary BHJ solar cell systems;

FIG. 26A shows the photo spectral response (PSR) of the ternary BHJ solar cell systems of a (PDBTTT-C:PBDTT-DPP):PC70BM system; (b) (PTB7:PBDTT-SeDPP):PC70BM system;

FIG. 26B shows the PSR of the ternary BHJ solar cell systems of a (PTB7:PBDTT-SeDPP):PC70BM system;

FIG. 27A shows transient photo-voltage (TPV) decay of the ternary BHJ solar cell systems of (PDBTTT-C:PBDTT-DPP):PC70BM under one-sun light bias;

FIG. 27B shows transient photo-voltage (TPV) decay of the ternary BHJ solar cell systems of (PTB7:PBDTT-SeDPP):PC70BM under one-sun light bias;

FIG. 27C shows transient photo-voltage (TPV) decay of the ternary BHJ solar cell systems of (P3HT:PBDTT-DPP):PC70BM under one-sun light bias;

FIG. 27D shows transient photo-voltage (TPV) decay of the ternary BHJ solar cell systems of (P3HT:PBDTT-SeDPP):PC70BM under one-sun light bias;

FIG. 28A shows GIWAXS patterns of PBDTTT-C;

FIG. 28B shows GIWAXS patterns of PBDTTT-C:PBDTT-DPP blending;

FIG. 28C shows GIWAXS patterns of PBDTT-DPP;

FIG. 28D shows GIWAXS patterns of P3HT:PBDTT-DPP blending;

FIG. 28E shows GIWAXS patterns of P3HT;

FIG. 28F shows GIWAXS patterns of PTB7;

FIG. 28G shows GIWAXS patterns of PTB7:PBDTT-SeDPP blending;

FIG. 28H shows GIWAXS patterns of PBDTT-SeDPP;

FIG. 28I shows GIWAXS patterns of P3HT:PBDTT-SeDPP blending;

FIG. 29A shows GIWAXS scanning curves for a PBDTTT-C:PBDTT-DPP blending system (out of plane);

FIG. 29B shows GIWAXS scanning curves for a PBDTTT-C:PBDTT-DPP blending system (in plane);

FIG. 29C shows GIWAXS scanning curves for a PTB7:PBDTT-SeDPP blending system (out of plane);

FIG. 29D shows GIWAXS scanning curves for a PTB7:PBDTT-SeDPP blending system (in plane);

FIG. 30A shows GIWAXS scanning curves for a P3HT:PBDTT-DPP blending system (out of plane);

FIG. 30B shows GIWAXS scanning curves for a P3HT:PBDTT-DPP blending system (in plane);

FIG. 30C shows GIWAXS scanning curves for a P3HT:PBDTT-SeDPP blending system (out of plane);

FIG. 30D shows GIWAXS scanning curves for a P3HT:PBDTT-SeDPP blending system (in plane);

FIG. 31A shows resonant soft X-ray scattering (RSoXS) profiles (open symbols) and calculated scattering intensities, I(q) (solid lines) of (PBDTTT-C:PBDTT-DPP):PC70BM, (PTB7:PBDTT-SeDPP):PC70BM, (P3HT:PBDTT-DPP):PC70BM and (P3HT:PBDTT-SeDPP):PC70BM;

FIG. 31B shows the pair distance distribution functions (PDDFs), P(r), of (PBDTTT-C:PBDTT-DPP):PC70BM, (PTB7:PBDTT-SeDPP):PC70BM, (P3HT:PBDTT-DPP):PC70BM and (P3HT:PBDTT-SeDPP):PC70BM;

FIG. 32A shows photoluminenscence spectra of PBDTTT-C:PBDTT-DPP blending system;

FIG. 32B shows photoluminenscence spectra of a PTB7:PBDTT-SeDPP blending system;

FIG. 32C shows photoluminenscence spectra of P3HT:PBDTT-DPP and P3HT:PBDTT-SeDPP blending systems; and

FIG. 33 displays a table showing device performance of (PBDTTT-C:Si-PCPDTBT):PC70BM BHJ ternary solar cell systems.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

Even with their imperfect characteristics, the rich set of low band gap polymers may be very helpful in improving state-of-art polymer solar cells if we can design OPV devices with multiple compatible polymers to expand the absorption range while at the same time maintaining other key parameters, such as open circuit voltage (Voc) and fill factor (FF).

Accordingly, some embodiments of the current invention are directed to broadening the absorption bandwidth of polymer solar cell by incorporating multiple absorber donors into the bulk-heterojunction (BHJ) active layer. In some embodiments, this approach can solve the limitation of the narrow absorption range of the organic semiconductors, without increasing fabrication complexity.

Recent progress in the development of new photovoltaic materials has made available a wide pool of high performance donor polymers with different absorption ranges that have been widely used in OPV research, for example: poly[4,8-bis-substituted-benzo[1,2-b:4,5-b0]dithiophene-2,6-diyl-alt-4-substituted-thieno[3,4-b]thiophene-2,6-diyl](PBDTTT-C) with Eg=1.60 eV; poly{2,6-4,8-di(5 ethylhexylthienyl) benzo[1,2-b;3,4-b]dithiophene-alt-5-dibutyloctyl-3,6-bis(5-bromothiophen-2-yl)pyrrolo[3,4-c]pyrrole-1,4-dione} (PBDTT-DPP) with Eg=1.46 eV; poly{4,6-(2-ethylhexyl-3-fluorothieno[3,4-b]thiophene-2-carboxylate)alt-2,6(4,8-bis(2-ethylhexyloxy)benzo[1,2-b:4,5-b]dithiophene)} (PTB7) with Eg=1.62 eV; (poly{2,6′-4,8-di(5-ethylhexylthienyl) benzo[1,2-b;3,4-b]dithiophene-alt-2,5-bis(2-butyloctyl)-3,6-bis(selenophene-2-yl)pyrrolo[3,4-c]pyrrole-1,4-dione} (PBDTT-SeDPP) with Eg=1.38 eV and P3HT with Eg=1.90 eV^{10, 18, 19, 20, 21, 22}. The ideal scenario is that the multiple polymers will work independently like parallel-connected devices, which will lead to a Jsc approximately equal to the summation of the two independent cells. However, in reality interactions between the two polymers are inevitable due to their different chemical and physical natures. It is well known that different high performance polymers have their own preferred morphologies in the active layer, including molecular orientation with respect to the substrate, crystallinity, domain size and so on. For instance, regio-regular P3HT tends to form edge-on lamellae in P3HT:PCBM films and exhibits much higher crystallinity compared with most other donor polymers, both of which are associated with its high photovoltaic performance. On the other hand, in many of the newer high performance donor polymers such as thienothiophene (TT) and benzo-dithiophene (BDT), BDT and N-alkylthieno[3,4-c]pyrrole-4,6-dione (TPD) based co-polymers, the preferred orientation to the substrate is face-on. This packing orientation is considered to be more advantageous to hole transportation in the vertical diode configuration such as photovoltaic. In addition, most of them show significantly more amorphous character in their films than P3HT. It is reasonable to infer that two blended polymers with different preferred packing orientations will interfere with one another when forming the morphology of the bulk heterojunction active layers. This will likely significantly affect the performance of resulting devices, since molecular interactions, domain size, and film morphology are clearly important issues in complex OPV systems.

Our strategy to improve the performance of multiple polymer systems according to some embodiments of the current invention is to optimize the compatibility of the individual donor materials, allowing them to work more like independent cells. The molecular compatibility of two or more polymers can be intuitively expected to correlate with various structural similarities. In the pool of available materials, PBDTTT-C, PBDTT-DPP, PTB7, and PBDTT-SeDPP, all have the rigid, planar benzodithiophene (BDT) unit in their backbone. Face-on with the substrate is the preferred orientation for these polymers in deposited active layers. Another important factor that determines the overall efficiency of multiple donor BHJ solar cells is the open circuit voltage (Voc). The Voc's of the multiple donor BHJ systems fell within the Voc values of the binary BHJ solar cells, which to a certain extent agrees with the results reported by Thompson et al., where tunable Voc was observed in their ternary systems. This tunable effect might be helpful for designing ternary solar cell systems with improved Voc as well.

From a synthetic perspective, good molecular compatibility between polymers appears most likely to be satisfied by materials with similar structures, such as shared monomer units along the polymer backbone. This device structure can help expand the absorption of the polymer active layer like the vertical tandem photovoltaic, while not increasing the complexity of the device fabrication process.

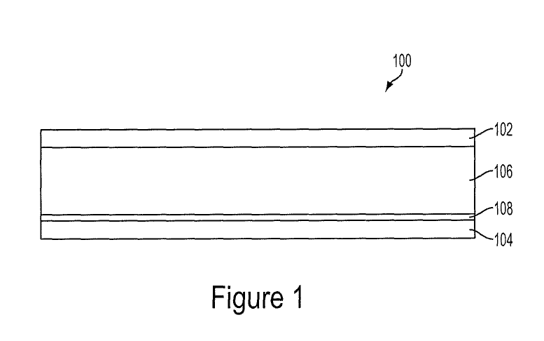

FIG. 1 is a schematic illustration of an organic photovoltaic device 100 according to an embodiment of the invention. The organic photovoltaic device 100 includes a first electrode 102 and a second electrode 104 proximate the first electrode with a space reserved therebetween. A bulk heterojunction active layer 106 is arranged between and in electrical connection with the first electrod 102 and the second electrode 104. The organic photovoltaic device 100 can have multiple layers of active materials and/or layers of material between the electrodes 102, 104 and the active layer 106 such as the layer 108, for example. One or both of the electrodes 102 and 104 can be transparent electrodes in some embodiments.

According to an embodiment of the invention, the bulk heterojunction active layer 106 comprises a blend of at least one of a plurality of organic electron donor materials and a plurality of electron acceptor materials. The plurality of organic electron donor materials have different photon absorption characteristics so as to provide an enhanced photon absorption bandwidth, and at least one of the plurality of organic electron donor materials and plurality of electron acceptor materials are structurally compatible so as to provide enhanced operation.

The term structurally compatible means that the different donor materials and/or different acceptor materials have individual structures such that, when blended together, the blend forms a structure with enhanced operation of the organic photovoltaic device. For example, the different donor molecules and different acceptor molecules, and/or monomers thereof, may have a longitudinal dimension that is longer than at least one of the two mutually orthogonal dimensions. The compatibility in the structures may then result in the longitudinal dimensions of the different types of molecules aligning substantially parallel with each other. Substantially parallel means sufficiently parallel to provide improved operation of the organic photovoltaic device.

According to an embodiment of the invention, the bulk heterojunction active layer 106 includes a blend of a plurality of organic electron donor materials and an electron acceptor material. The plurality of organic electron donor materials have different photon absorption characteristics so as to provide an enhanced photon absorption bandwidth, and the plurality of organic electron donor materials are structurally compatible so as to provide enhanced operation as compared to a plurality of structurally in-compatible organic electron donor materials. In other embodiments, there can be a plurality of acceptor materials that are structurally compatible along with a single donor material. In further embodiments, there can be a plurality of donor materials that are structurally compatible and a plurality of acceptor materials that are structurally compatible.

In some embodiments, at least one of the plurality of organic electron donor materials or the plurality of electron acceptor materials includes organic small molecules. In some embodiments, at least one of the plurality of organic electron donor materials or the plurality of electron acceptor materials includes an organic polymer. Some embodiments can include combinations of both organic polymers and organic small molecules for either or both of the donor materials and acceptor materials.

In some embodiments, at least one of the plurality of organic electron donor materials or the plurality of electron acceptor materials are structurally compatible resulting from molecular alignment.

Some concepts of the current invention are explained by way of particular examples. The general concepts of the current invention are not limited to the particular examples.

### Examples

The material pool in this study includes poly[4,8-bis-substituted-benzo[1,2-b:4,5-b0]dithiophene-2,6-diyl-alt-4-substituted-thieno[3,4-b]thiophene-2,6-diyl](PBDTTT-C) with Eg=1.60 eV; poly{2,6-4,8-di(5ethylhexylthienyl) benzo[1,2-b;3,4-b]dithiophene-alt-5-dibutyloctyl-3,6-bis(5-bromothiophen-2-yl)pyrrolo[3,4-c]pyrrole-1,4-dione} (PBDTT-DPP) with Eg=1.46 eV; poly {4,6-(2-ethylhexyl-3-fluorothieno[3,4-b]thiophene-2-carboxylate)alt-2,6(4,8-bis(2-ethylhexyloxy)benzo[1,2-b:4,5-b]dithiophene)} (PTB7) with Eg=1.62 eV; (poly{2,6′-4,8-di(5-ethylhexylthienyl) benzo[1,2-b;3,4-b]dithiophene-alt-2,5-bis(2-butyloctyl)-3,6-bis(selenophene-2-yl)pyrrolo[3,4-c]pyrrole-1,4-dione} (PBDTT-SeDPP) with Eg=1.38 eV and P3HT with Eg=1.90 eV.

These photovoltaic materials have been reported with good device performance, but substantially different processing methods. Choosing a solvent that is compatible with each material represents a particularly difficult challenge. PBDTTT-C and PTB7 generally work best when deposited from chlorobenzene (CB) with efficiencies of 6.58% and 7.4% respectively, with their performance degrading slightly when processed in dichlorobenzene (DCB)^{10, 20}. However, polymer PBDTT-DPP and PBDTT-SeDPP are not sufficiently soluble in CB to form uniform films, so they are normally processed from DCB^{18, 22}. To balance these ideal processing differences and set up an appropriate baseline, all the BHJ devices discussed herein are fabricated using DCB as a solvent.

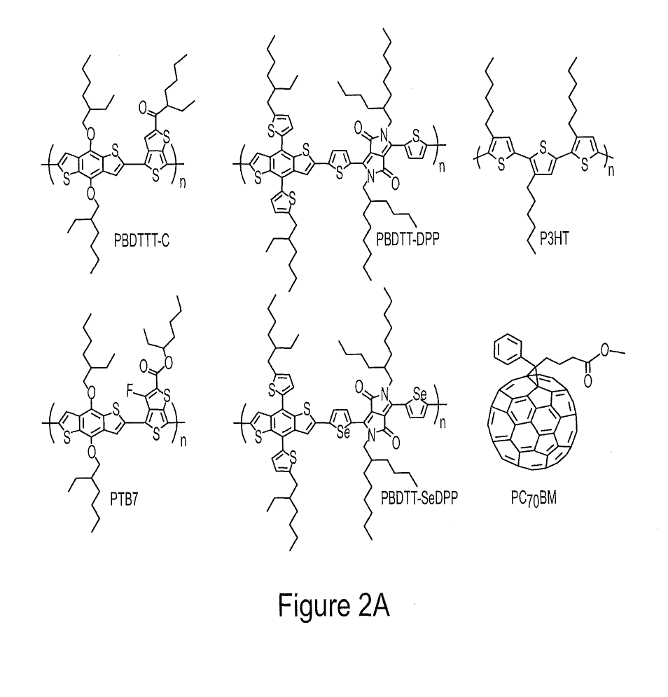

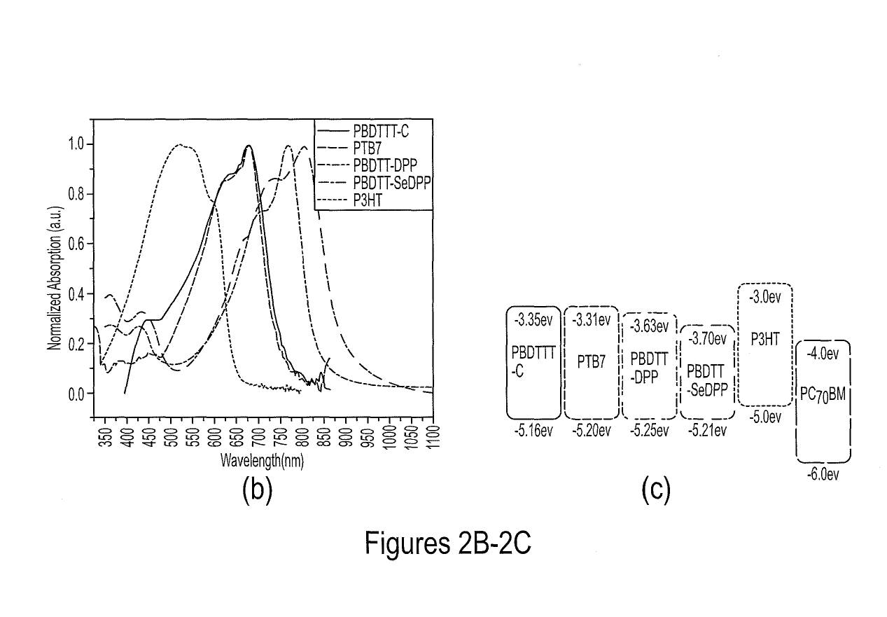

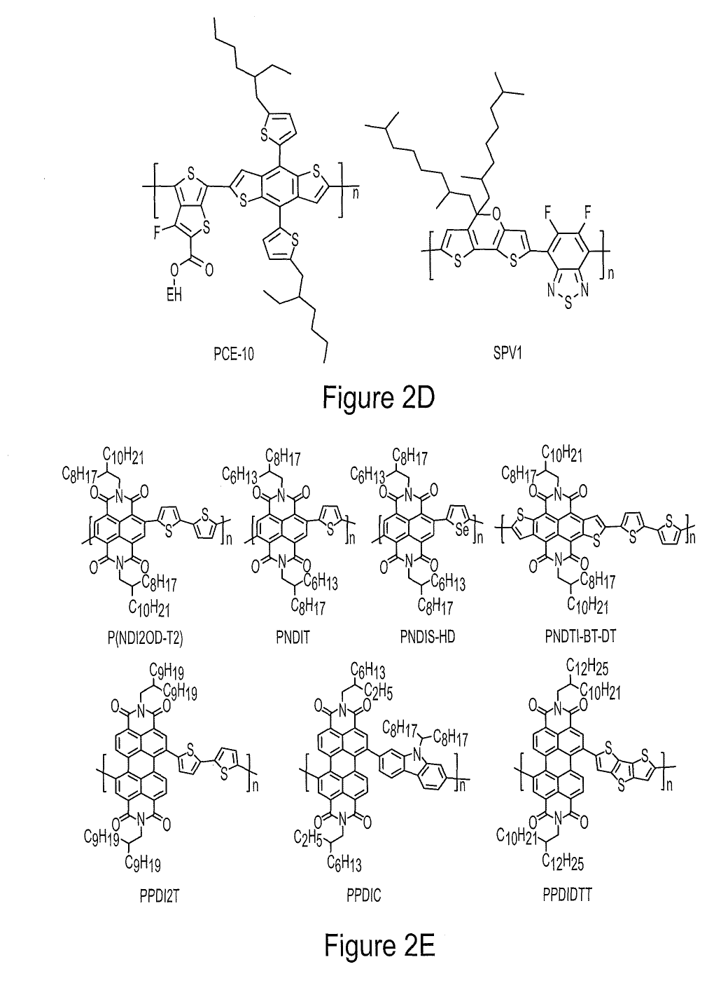

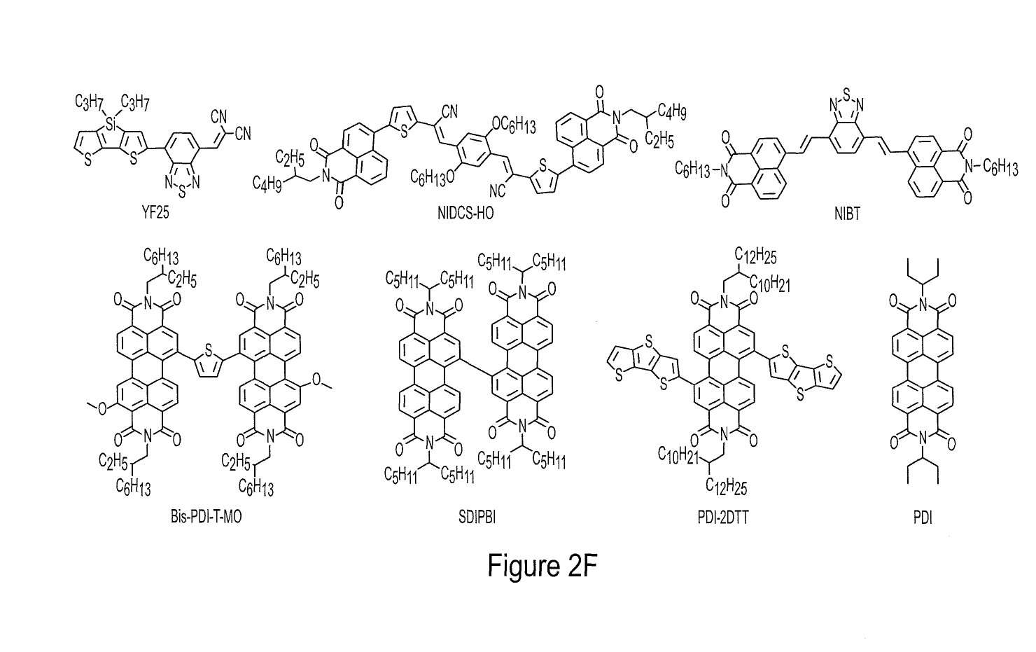

FIGS. 2A and 2B show schematic chemical structures and absorption spectra of a plurality of materials used according to an embodiment of the invention, and FIG. 2C shows energy band diagrams of the material pool according to an embodiment of the invention. FIG. 2D shows a schematic illustration of chemical structures of additional donor materials used according to an embodiment of the invention. The donor materials that can be used are not limited to those shown in FIGS. 2A and 2D, but include any polymers that have a backbone corresponding to any of the donor materials shown in FIGS. 2A and 2D. FIGS. 2E and 2F show a schematic illustration of chemical structures of additional acceptor materials used according to an embodiment of the invention. The acceptor materials that can be used are not limited to those shown in FIGS. 2A, 2E and 2F, but include any polymers that have a backbone corresponding to any of the acceptor materials shown in FIGS. 2A, 2E and 2F.

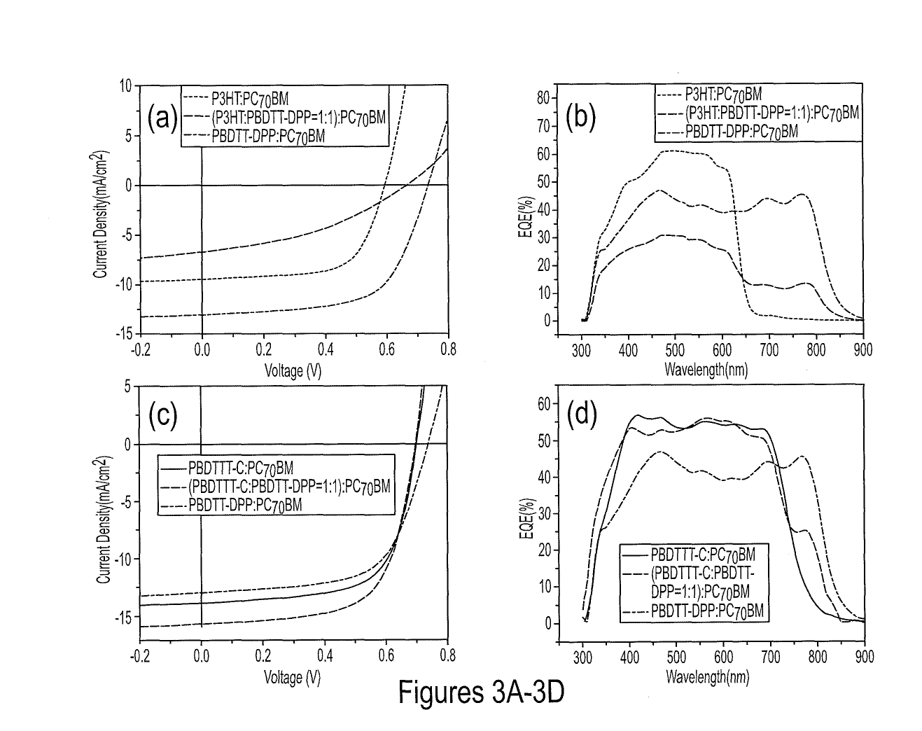

In the material pool shown in FIG. 2C, RR-P3HT has an absorption edge around 650 nm, and is expected to be spectrally matched to PBDTT-DPP with its absorption edge of roughly 850 nm. We first examined the photovoltaic performance of the ternary system containing these two polymer donors. FIG. 3A shows a current-voltage (J-V) curve of the (P3HT:PBDTT-DPP):PC₇₀BM ternary BHJ solar cell system measured under one sun conditions (100 mW/cm²). FIG. 3B shows an external quantum efficiency (EQE) measurement of the (P3HT:PBDTT-DPP):PC₇₀BM ternary BHJ solar cell system. FIG. 3C shows a J-V curve of the (PBDTTT-C:PBDTT-DPP):PC₇₀BM ternary BHJ solar cell system measured under one sun conditions (100 mW/cm²). FIG. 3D shows an EQE measurement of the (PBDTTT-C:PBDTT-DPP):PC₇₀BM ternary BHJ solar cell system. The devices with blended polymers present a much broader absorption range and photocurrent response, as shown in FIG. 3B, but do not produce an overall enhancement of photocurrent due to significant reductions in EQE, particularly in the P3HT response region. Additionally, the fill factor decreased markedly from ˜65% to less than 40% in the mixed polymer device.

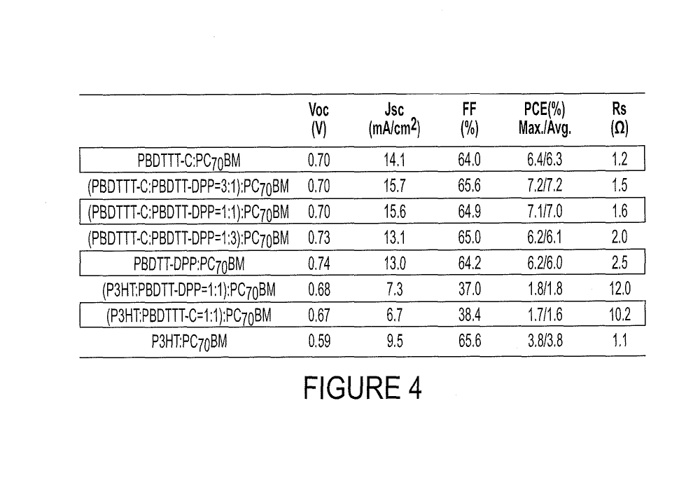

Taking both molecular orientation and absorption characteristics into consideration, a ternary blending system using PBDTTT-C:PBDTT-DPP as donors was studied. FIG. 3C and FIG. 3D show the device results of the (PBDTTT-C:PBDTT-DPP):PC70BM ternary BHJ solar cells, along with their two binary BHJ solar cells as control devices. Individual PBDTTT-C:PC70BM and PBDTT-DPP:PC70BM solar cells have optimized power conversion efficiency values of 6.4% and 6.2%, respectively. The EQE spectrum of the ternary BHJ device of (PBDTTT-C:PBDTT-DPP=1:1):PC70BM distinctively shows the combined photoresponse of both polymer donors, and as a result the overall photocurrent increases to 15.7 mA/cm², surpassing each binary reference system. Surprisingly, the ternary BHJ photovoltaic devices still maintain a very high FF of 65%. The optimized ternary solar cells outperform the reference binary cells at certain blending ratios, specifically 3:1 and 1:1. The table in FIG. 4 shows device performance of the (PDBTTT-C:PBDTT-DPP):PC70BM, (P3HT:PBDTT-DPP):PC70BM, and (P3HT:PBDTTT-C):PC70BM ternary systems.

The series resistance (Rs) typically fell between 1.2-2.5Ω in the (PBDTTT-C:PBDTT-DPP):PC70BM ternary BHJ system, and was much higher (>10Ω) in the low performance (P3HT:PBDTT-DPP):PC70BM ternary system. Assuming that the active layer to electrode contact was similar in each of the devices, the higher Rs very likely arose from the change of electrical transport properties within the BHJ, which will be described later in this manuscript. Clearly, the dramatically different effects of P3HT and PBDTTT-C when added to PDBTT-DPP:PC70BM mixtures to produce ternary BHJ systems infers that structurally compatible polymers can efficiently coexist and improve device performance by broadening the range of photocurrent collection without disturbing the morphology of the BHJ. Using structurally incompatible polymers, such as P3HT and PBDTT-DPP, appears to have the opposite effect, ultimately causing severe reductions in device performance.

An active material, e.g., an organic electron donor material or an organic electron acceptor material, can show a preferred orientation with respect to a substrate when the active material is part of an active layer in an organic photovoltaic device. An active material can preferentially adopt, for example, an edge-on orientation or a face-on orientation with respect to a substrate. The orientation can describe manner in which π-π stacking occurs in the active layer, e.g., whether the π-π stacking planes are substantially orthogonal to the substrate, or substantially parallel to the substrate.

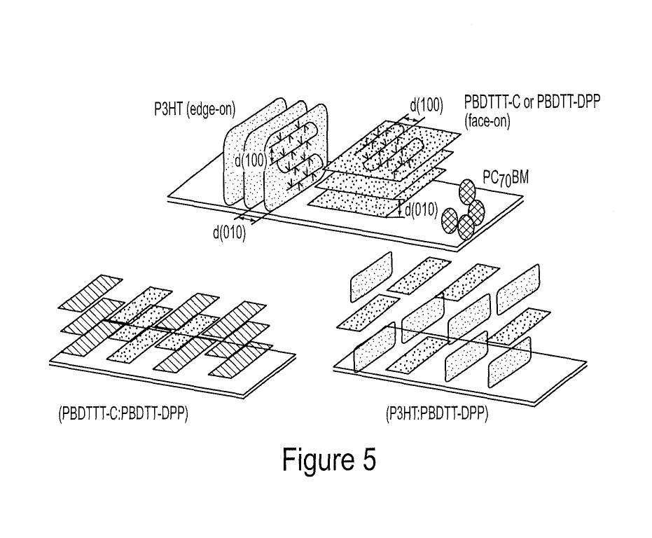

The terms “edge-on” and “face-on” are not intended to indicate to a precise angle with respect to a substrate. It will be understood that an “edge-on” orientation tends toward being orthogonal to a substrate, whereas a “face-on” orientation tends toward being parallel to a substrate. FIG. 5 provides a schematic illustration of polymers demonstrating “edge-on” and “face-on” orientations.

In some embodiments, a polymer blend can include two or more different polymers which individually have the same preferred orientation with respect to a substrate. For example, the polymer blend can include a first polymer which has a preferred edge-on orientation, and a second polymer which likewise has a preferred edge-on orientation. In this scenario, it may be expected that the two polymers, when blended, will both prefer an edge-on orientation and demonstrate π-π stacking in an edge-on orientation.

In another example, the polymer blend can include a first polymer which has a preferred face-on orientation, and a second polymer which likewise has a preferred face-on orientation. In this scenario, it may be expected that the two polymers, when blended, will both prefer a face-on orientation and demonstrate π-π stacking in a face-on orientation.

In contrast, if the polymer blend includes a first polymer which has a preferred edge-on orientation, and a second polymer which instead has a preferred face-on orientation, it may be expected that the two polymers, when blended, will demonstrate a smaller degree of π-π stacking than a blend in which the polymers both prefer the same orientation.

Two (or more) active materials may be described as structurally compatible when the two (or more) materials share the same preferred orientation with respect to a substrate.

The non-conjugated polymer side chain is largely insulating, while the conjugated backbone is conductive. When two polymers with different molecular orientation are mixed, as in the P3HT:PBDTT-DPP blended system, the non-conductive side chain and the conductive conjugated backbone are likely to be stacked with one another in an alternating pattern. This reduces the crystalline length, disrupts long range charge transport and lowers the charge carrier mobility of the blended film. The scenario is illustrated in FIG. 5, which is a schematic illustration of the molecular stacking and interactions in the polymer blends of (PBDTTT-C:PBDTT-DPP) and (P3HT:PBDTT-DPP) according to an embodiment of the invention. The charge carrier mobility in semiconducting polymers has been proved to be correlated with the preferred orientation of π-π stacking, the π-π stacking coherence length and the degree of polymer aggregation (or crystallinity)³⁹⁻⁴³. All of these structural characteristics remain relatively unchanged in the well-performed ternary system, while the confrontational effects are observed in the poorly-performed ternary solar cell system.

Blends of different organic polymers and/or organic small molecules may be used according to some embodiments of the current invention if good π-π stacking of the blend is obtained. When the stacking of the different types of molecules are parallel, good compatibility is achieved. In cases in which the stacking of one type of molecule is orthogonal to the other type of molecule, poor compatibility is achieved. In some embodiments the stacking can be very precisely close to parallel, while in other embodiments the stacking can be within 10°, within 20°, within 30°, or within 40°, for example.

We have further applied this model to a separate ternary blends containing PTB7 and PBDTT-SeDPP. PTB7 has a similar molecular structure and “edge-on” molecular orientation to that of PBDTTT-C, and its absorption edge is blue shifted by roughly 10 nm, but the overall photovoltaic performance is better^{10, 20}. PBDTT-SeDPP is an improved form of PBDTT-DPP, with its absorption edge red shifted by 50 nm to roughly a 900 nm onset²². These properties of PTB7 and PBDTT-SeDPP are expected to make them even better ternary blend polymer solar cell systems.

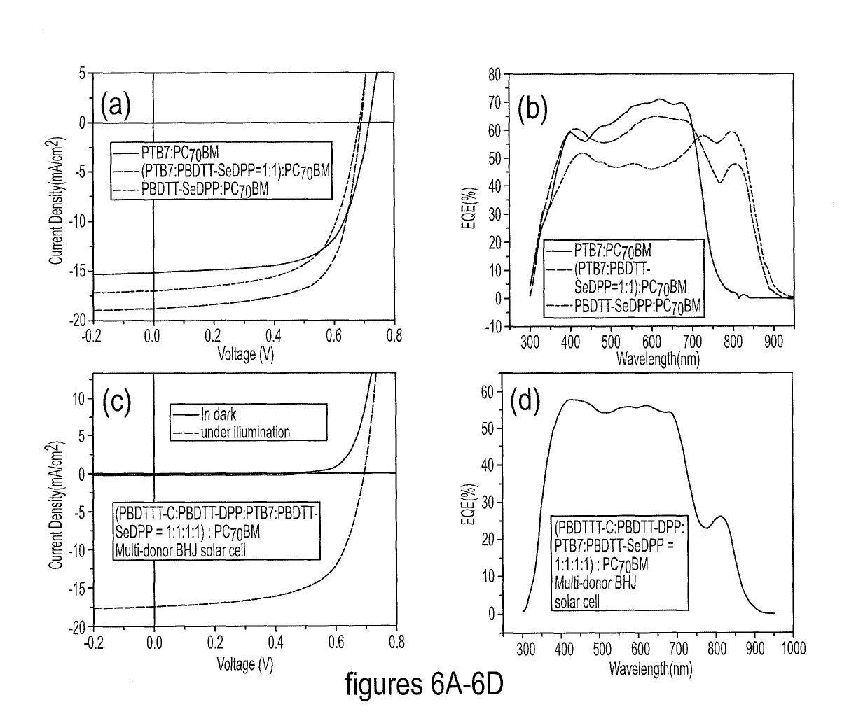

The ternary (PTB7:PBDTT-SeDPP=1:1):PC70BM device produced an efficiency of 8.7%, which is significantly higher than that of devices made from its individual donor materials. For comparison, the PTB7:PC70BM binary BHJ solar cell produced 7.2% efficiency, and the PBDTT-SeDPP:PC70BM binary BHJ solar cell achieved 7.2% as well (both binary cells used DCB as solvent), which gives the blended donor devices a 21% relative enhancement in PCE with respect to the binary cells. This is reflected in FIG. 6, described below.

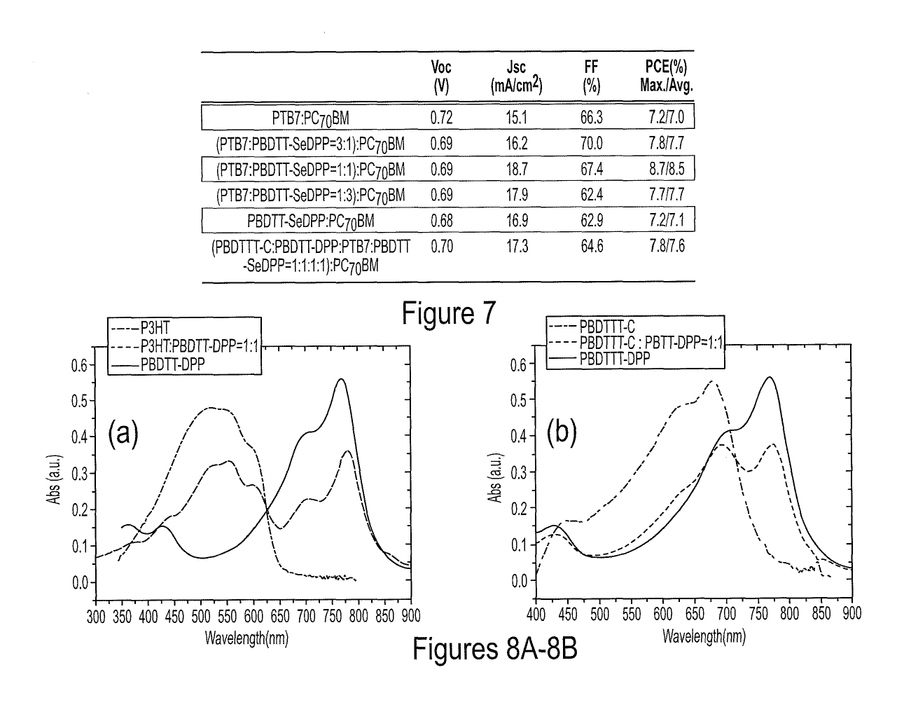

The table in FIG. 7 shows device performance of the (PTB7:PBDTT-SeDPP):PC70BM and (PBDTTT-C:PBDTT-DPP:PTB7:PBDTT-SeDPP):PC70BM multiple donor BHJ systems. The ternary BHJ photovoltaic outperformed each binary BHJ photovoltaic at three different polymer blending ratios—25%, 50% and 75% PBDTT-SeDPP. The D/A ratio in all of the devices was 1:2. The ternary BHJ photovoltaic device may be further improve by optimizing the D/A ratio and by changing the solvent or using a co-solvent system, since the optimized solvents for PTB7 and PBDTT-SeDPP are different as mentioned in the previous section.

Since both the PBDTTT-C:PBDTT-DPP and PTB7:PBDTT-SeDPP systems appear to provide good structural compatibility and device performance, it may enable an efficient BHJ polymer solar cell comprising these four different donor polymers. Indeed, results from a four-donor BHJ solar cell presented the very reasonable performance of 7.8% efficiency, with EQE values close to those of the constituent polymers. FIG. 6A shows J-V characteristics of a (PTB7:PBDTT-SeDPP):PC70BM ternary BHJ solar cell system measured under one sun conditions (100 mW/cm²). FIG. 6B shows EQE measurements of a (PTB7:PBDTT-SeDPP):PC70BM ternary BHJ solar cell system. FIG. 6C shows J-V characteristics of a PDBTTT-C:PBDTT-DPP:PTB7:PBDTT-SeDPP):PC70BM multi-donor BHJ solar cell system, measured under one sun conditions (100 mW/cm²). FIG. 6D shows EQE measurements of a (PDBTTT-C:PBDTT-DPP:PTB7:PBDTT-SeDPP):PC70BM multi-donor BHJ system. The results conceptually indicate that mixing two or even more donor materials into one BHJ is possible as long as they exhibit sufficient structural compatibility.

Photovoltaic devices were fabricated on indium tin oxide (ITO) coated glass substrates that served as the anode. The ITO substrates were ultrasonically cleaned in detergent, deionized water, acetone, and isopropanol. A layer of 30 nm PEDOT:PSS (poly(3,4-ethylenedioxythiophene):poly(styrene sulfonate)) (Baytron P VPAI 4083, Germany) was spin-coated onto the ITO substrate and was dried in air at 120° C. for 10 minutes. Polymer/PC70BM or Polymer blend/PC70BM were dissolved in 1,2-dichlorobenzene (O-DCB) and were spin-coated on top of the PEDOT layer. Finally, the Ca/Al cathode (100 nm) was vacuum evaporated onto the annealed photoactive layer.

The reference P3HT:PC70BM solar cells were spin coated at 800 rpm with a 1:1 D/A ratio followed by a “slow growth” method, as reported in the literature⁹, with a thickness of approximately 210 nm. For both the (PBDTTT-C:PBDTT-DPP):PC70BM and (PTB7:PBDTT-SeDPP):PC70BM ternary BHJ solar cell systems, the D/A ratio was kept at 1:2, and each was spinning casted from (DCB+3% DIO) solutions. The optimized thicknesses for PBDTTT-C:PC70BM, (PBDTTT-C:PBDTT-DPP=1:1):PC70BM and PBDTT-DPP:PC70BM solar cells were 110 nm, 130 nm, and 105 nm, respectively. In the (PTB7:PBDTT-SeDPP):PC70BM ternary BHJ solar cell system, the optimized thicknesses for PTB7:PC70BM, (PTB7:PBDTT-SeDPP=1:1):PC70BM and PBDTT-DPP:PC70BM solar cells were 95 nm, 115 nm, and 100 nm, respectively. For the four-donor BHJ solar cell, the active layer was spin-cast from the combined solution of (PBDTTT-C:PBDTT-DPP=1:1):PC70BM and (PTB7:PBDTT-SeDPP=1:1):PC70BM with a 1:1 vol. ratio, so that the D/A ratio was 1:2, and the device thickness was roughly 120 nm.

The effective area of the devices was 0.1 cm². The J-V measurements of the photovoltaic devices were conducted using a Keithley 236 Source-Measure unit. A xenon lamp with an AM1.5G filter (NEWPORT) simulated 1 sun conditions, and the light intensity at the sample was 100 mW/cm², calibrated with a Mono-Si photodiode with a KG-5 color filter. The reference diode is traceable to NREL certification. EQE measurements were conducted with an integrated system (system name) from EnliTech, Taiwan.

As can be inferred from the above discussion, the above-mentioned concepts can be implemented in a variety of arrangements in accordance with embodiments of the invention. Accordingly, although the present invention has been described in certain specific aspects, many additional modifications and variations would be apparent to those skilled in the art. It is therefore to be understood that the present invention may be practiced otherwise than specifically described. Thus, embodiments of the present invention should be considered in all respects as illustrative and not restrictive.

According to some embodiments of the current invention, multiple polymeric or organic semiconductors can be blended in one bulk heterojunction for increasing the absorption bandwidths of the solar cell and hence the short circuit current and power conversion efficiency of the organic photovoltaic systems. The blended materials can be polymers and/or organic small molecules.

According to some embodiments of the current invention, the blended material systems can be (a) multiple p-type materials blended with one n-type material, (b) multiple n-type materials blended with one p-type material, or (c) multiple p-type materials blended with multiple n-type materials. Both p-type and n-type materials can include polymer(s) and/or organic small molecules. The blended materials can be two materials, or more than two materials, without limitation in the number of blended materials.

According to some embodiments of the current invention, the heterojunction active layer is a blend comprising PDBTTT-C and PBDTT-DPP.

According to some embodiments of the current invention, the bulk heterojunction active layer is a blend comprising PTB7 and PBDTT-SeDPP.

According to some embodiments of the current invention, the said bulk heterojunction active layer is a blend comprising PBDTTT-C, PBDTT-DPP, PTB7, and PBDTT-SeDPP.

According to some embodiments of the current invention, the bulk heterojunction active layer comprises a blend of a plurality of organic electron donor materials.

According to some embodiments of the current invention, the plurality of organic electron donor materials are selected from the group of organic electron donor materials consisting of PBDTTT-C, PBDTT-DPP, PTB7, PBDTT-SeDPP, PCE10, SPV1 and polymers that have a backbone corresponding to any one of the polymers thereof.

According to some embodiments of the current invention, plurality of organic electron donor materials consist essentially of PDBTTT-C and PBDTT-DPP.

According to some embodiments of the current invention, the plurality of organic electron donor materials consist essentially of PTB7 and PBDTT-SeDPP.

According to some embodiments of the current invention, the plurality of organic electron donor materials consist essentially of PBDTTT-C, PBDTT-DPP, PTB7, and PBDTT-SeDPP.

According to some embodiments of the current invention, the blended n-type materials can be non-fullerene based small molecules and polymers with good structural compatibility. Such materials have particular advantages over the fullerene based n-type materials due to their low cost and high stability.

According to some embodiments of the current invention, the blended materials can be deposited from a solution process, such as, but not limited to, spin coating, spray coating, blend coating, injek printing, etc. According to some embodiments of the current invention, the blended materials can alternatively, or additionally, be deposited by a thermal evaporation process and/or any other deposition process that is suitable for the particular application.

According to some embodiments of the current invention, the blended materials can be used for single layer, tandem or multiple-junction photovoltaic devices.

According to some embodiments of the current invention, the blended materials can be used in regular OPV device structures and/or inverted structures, including regular or inverted multiple-junction structures.

According to some embodiments of the current invention, the blended materials can be selected through molecular compatibility information, such as similar molecular structure, molecular packing orientation, and/or crystallinity.

According to some embodiments of the current invention, a method of producing a composition for a bulk heterojunction active layer of an organic photovoltaic device includes selecting a first organic electron donor material, selecting a first electron acceptor material, and selecting at least one of a second organic electron donor material that is structurally compatible with the first organic electron donor material or a second electron acceptor material that is structurally compatible with the first electron acceptor material. The method further includes blending all materials selected to provide the composition.

### Additional Examples

Broadening the absorption bandwidth of polymer solar cell by incorporating multiple absorber donors into the bulk-heterojunction (BHJ) active layer is a straightforward way of resolving the narrow absorption of organic semiconductors. However, this leads to a much more complicated system, and previous efforts have met with limited success. In this manuscript, we investigate the multi-polymer photovoltaic systems with particular interest in the structural compatibility of the donor materials. Several dual-donor and multi-donor BHJ polymer solar cells based on a material pool with different absorption ranges and preferred molecular structures were studied. The results show clearly that the compatibility of the polymers' structure and molecular orientation plays a critical role in the success of the resulting multi-polymer BHJ solar cell. Selection rules for molecular compatibility were realized, through which we are able to demonstrate two successful ternary BHJ solar cell systems with up to 8.7% power conversion efficiency, outperforming their corresponding binary devices. The demonstration of a 7.8% four-donor BHJ photovoltaic device further supports this model. These results establish the general use of multi-donor BHJ to overcome the absorption limitation, and achieve both high performance and fabrication simplicity for organic solar cells.

Polymer photovoltaic cells have shown great potential as a means to harvest solar energy in a highly processable and cost-effective manner¹⁻⁵. Typical polymer solar cells consist of a mixture of a polymer (or organic small molecule) donor and C-60 derivative acceptor as the photo-active layer. In BHJ organic solar cells, the absorbed incident photons generate tightly bound electron-hole pairs, which are then dissociated into electrons and holes at the nearby donor/acceptor interface. The electrons and holes are then transported to their respective electrodes⁶⁻⁸.

Research efforts in the last decade or so have significantly improved organic solar cell performance⁹⁻¹⁴, and power conversion efficiency (PCE) values beyond 10% have recently been achieved¹⁵⁻¹⁶. Over the years, significant research efforts have been put into developing low band gap polymers to extend the absorption and harvest more solar energy. Nevertheless, unlike the continuous band structure of inorganic semiconductors like Si, the molecular orbital energy level of organic semiconductors is narrow, which makes it challenging to obtain the panchromatic absorption coverage with a single organic semiconductor. This is one of the reasons that polymer solar cells invariably exhibit low short circuit current (Jsc), compared with commercial inorganic solar cells. In addition, it has been very difficult to achieve as high an external quantum efficiency (EQE) in low band gap polymer systems (E_{g}<1.4 eV) as in traditional polymer systems such as poly(3-hexyl thiophene) (P3HT) with reported EQE values of over 70%¹⁷. Even with their imperfect characteristics, this rich set of low band gap polymers may be very helpful in improving state-of-art polymer solar cells if we can design OPV devices with multiple compatible polymers to expand the absorption range while at the same time maintaining other key parameters, such as open circuit voltage (Voc) and fill factor (FF).

Recent progress in the development of new photovoltaic materials has made available a wide pool of high performance donor polymers with different absorption ranges that have been widely used in OPV research, for example: poly[4,8-bis-substituted-benzo[1,2-b:4,5-b0]dithiophene-2,6-diyl-alt-4-substituted-thieno[3,4-b]thiophene-2,6-diyl](PBDTTT-C) with E_{g}=1.60 eV; poly{2,6-4,8-di(5ethylhexylthienyl) benzo[1,2-b;3,4-b]dithiophene-alt-5-dibutyloctyl-3,6-bis(5-bromothiophen-2-yl)pyrrolo[3,4-c]pyrrole-1,4-dione} (PBDTT-DPP) with E_{g}=1.46 eV; poly{4,6-(2-ethylhexyl-3-fluorothieno[3,4-b]thiophene-2-carboxylate)alt-2,6(4,8-bis(2-ethylhexyloxy)benzo[1,2-b:4,5-b]dithiophene)} (PTB7) with E_{g}=1.62 eV; (poly{2,6′-4,8-di(5-ethylhexylthienyl) benzo[1,2-b;3,4-b]dithiophene-alt-2,5-bis(2-butyloctyl)-3,6-bis(selenophene-2-yl)pyrrolo[3,4-c]pyrrole-1,4-dione} (PBDTT-SeDPP) with E_{g}=1.38 eV and P3HT with E_{g}=1.90 eV^{10, 18, 19, 20, 21, 22} Unfortunately, very few successful ternary BHJ polymer photovoltaic cell structures have been reported that surpass the efficiency of their corresponding binary BHJ devices²³. The ideal scenario is that the multiple polymers will work independently like parallel-connected devices, which will lead to a Jsc approximately equal to the summation of the two independent cells. However, in reality interactions between the two polymers are inevitable due to their different chemical and physical natures. It is well known that different high performance polymers have their own preferred morphologies in the active layer, including molecular orientation with respect to the substrate, crystallinity, domain size, and so on. For instance, regio-regular P3HT tends to form edge-on lamellae in P3HT:PCBM films and exhibits much higher crystallinity compared with most other donor polymers, both of which are associated with its high photovoltaic performance^{17, 24}. On the other hand, in many of the newer high performance donor polymers such as thienothiophene (TT) and benzo-dithiophene (BDT), BDT and N-alkylthieno[3,4-c]pyrrole-4,6-dione (TPD) based co-polymers^{19, 25, 26, 27}, the preferred orientation to the substrate is face-on^{19, 27, 28}. This packing orientation is considered to be more advantageous to hole transportation in the vertical diode configuration such as photovoltaic^{28, 29}. In addition, most of them show significantly more amorphous character in their films than P3HT²⁸. It is reasonable to infer that two blended polymers with different preferred packing orientations will interfere with one another when forming the morphology of the bulk heterojunction active layers. This will likely significantly affect the performance of resulting devices, since molecular interactions, domain size, and film morphology are clearly important issues in complex OPV systems.

In this manuscript, we focus on establishing a useful system of rules for designing multi-polymer/fullerene derivative blends based on their individual structure-property relationships. The Grazing Incidence X-ray Scattering (GIXS) technique is used to determine the molecular packing information within the solid state films, which can then be correlated with their photovoltaic performance. The ternary polymer blend/fullerene systems studied herein each have both a high band gap polymer and a low band gap polymer in order to cover a broader section of the solar spectrum. FIGS. 2A-2F shows the materials used in this study, all of which have previously been reported as high performance photovoltaic materials featuring different absorption ranges and different molecular stacking preferences. For example, PBDTTT-C and P3HT both have demonstrated high EQE and PCE values, but one prefers edge-on and the other one prefers face-on orientation in OPV absorber films.

These photovoltaic materials have been reported with good device performance, but substantially different processing methods. Choosing a solvent that is compatible with each material represents a particularly difficult challenge. PBDTTT-C and PTB7 generally work best when deposited from chlorobenzene (CB) with efficiencies of 6.58% and 7.4% respectively, with their performance degrading slightly when processed in dichlorobenzene (DCB)^{10, 20}. However, polymer PBDTT-DPP and PBDTT-SeDPP are not sufficiently soluble in CB to form uniform films, so they are normally processed from DCB^{18, 22}. To balance these ideal processing differences and set up an appropriate baseline, all the BHJ devices discussed here are fabricated using DCB as a solvent.

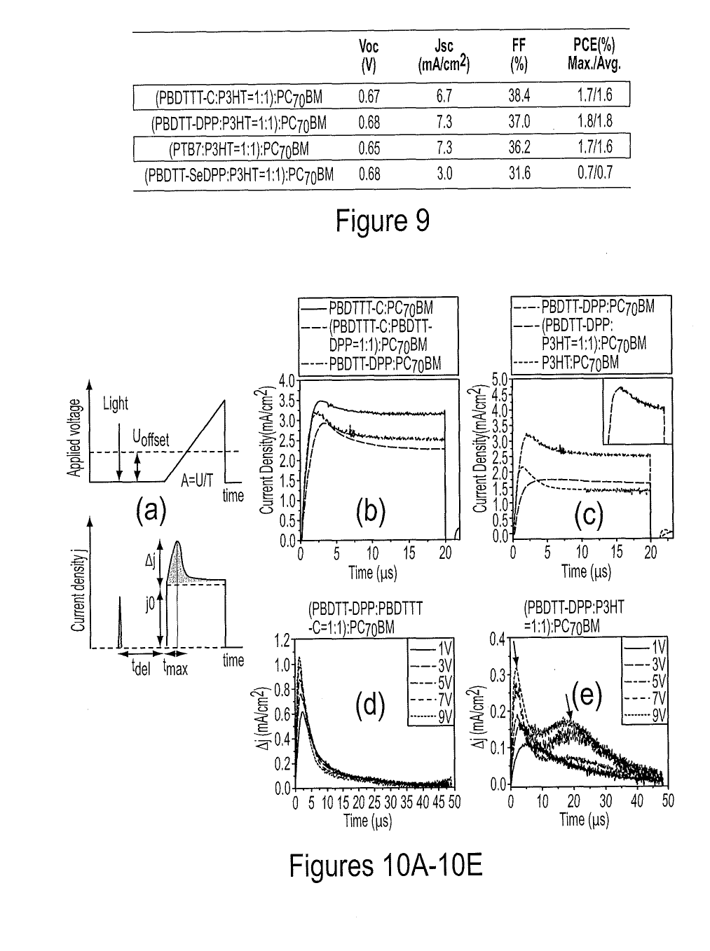

In the material pool shown in FIGS. 2A-2F, RR-P3HT has an absorption edge around 650 nm, and is expected to be spectrally matched to PBDTT-DPP with its absorption edge of roughly 850 nm. We first examined the photovoltaic performance of a ternary system containing these two polymer donors. FIG. 8A shows the absorption spectrum for (P3HT:PBDTT-DPP) dual donor polymer blends, and FIG. 8B shows the absorption spectrum for (PBDTTT-C:PBDTT-DPP) dual donor polymer blends. The devices with blended polymers present a much broader absorption range, as shown in FIGS. 8A and 8B, and photocurrent response, as shown in FIG. 3B, but do not produce an overall enhancement of photocurrent due to significant reductions in EQE, particularly in the P3HT response region. Additionally, the fill factor decreased markedly from ˜65% to less than 40% in the mixed polymer device. These results are not surprising, as photovoltaic devices employing blended donors have produced even worse performance in many circumstances. Results obtained from low band gap polymers (PBDTTT-C, PBDTT-DPP, PTB7, or PBDTT-SeDPP), and RR-P3HT ternary BHJ solar cells are summarized in the table shown in FIG. 9.

Our strategy to improve the performance of multiple polymer systems is to optimize the compatibility of the individual donor materials, allowing them to work more like independent cells. The molecular compatibility of two or more polymers can be intuitively expected to correlate with various structural similarities. In the pool of available materials, PBDTTT-C, PBDTT-DPP, PTB7, and PBDTT-SeDPP, all have the rigid, planar benzodithiophene (BDT) unit in their backbone. Face-on with the substrate is the preferred orientation for these polymers in deposited active layers.

Taking both molecular orientation and absorption characteristics into consideration, a ternary blending system using PBDTTT-C:PBDTT-DPP as donors was studied. FIG. 3C and FIG. 3D show the device results of the (PBDTTT-C:PBDTT-DPP):PC₇₀BM ternary BHJ solar cells, along with their two binary BHJ solar cells as control devices. Individual PBDTTT-C:PC₇₀BM and PBDTT-DPP:PC₇₀BM solar cells have optimized power conversion efficiency values of 6.4% and 6.2%, respectively. The EQE spectrum of the ternary BHJ device of (PBDTTT-C:PBDTT-DPP=1:1):PC₇₀BM distinctively shows the combined photoresponse of both polymer donors, and as a result the overall photocurrent increases to 15.7 mA/cm², surpassing each binary reference system.

Surprisingly, the ternary BHJ photovoltaic devices still maintain a very high FF of 65%. The optimized ternary solar cells outperform the reference binary cells at certain blending ratios, as shown in the table in FIG. 4, specifically 3:1 and 1:1. The series resistance (Rs) typically fell between 1.2-2.5Ω in the (PBDTTT-C:PBDTT-DPP):PC₇₀BM ternary BHJ system, and was much higher (>10Ω) in the low performance (P3HT:PBDTT-DPP):PC₇₀BM ternary system. Assuming that the active layer to electrode contact was similar in each of the devices, the higher Rs very likely arose from the change of electrical transport properties within the BHJ, which will be studied later in this manuscript. Clearly, the dramatically different effects of P3HT and PBDTTT-C when added to PDBTT-DPP:PC₇₀BM mixtures to produce ternary BHJ systems infers that structurally compatible polymers can efficiently coexist and improve device performance by broadening the range of photocurrent collection without disturbing the morphology of the BHJ. Using structurally incompatible polymers, such as P3HT and PBDTT-DPP, appears to have the opposite effect, ultimately causing severe reductions in device performance.

Charge transport is critical to organic photovoltaic device performance, especially in polymer solar cells with multiple donors. Unfavorable interactions between different polymers within the active layer can easily inhibit charge transport capabilities and hence limit device efficiency if the polymers are not properly designed. In order to further study the charge carrier mobility of the photovoltaic devices under operating conditions, photo-charge extraction by linearly increasing voltage (CELIV) measurements were conducted using both the binary and ternary BHJ systems. FIG. 10A shows the experimental setup of the photo-CELIV measurements according to an embodiment of the invention. The free carriers were excited by a 590 nm dye laser and extracted by a linearly increasing voltage after a 5 μs delay time. The offset was −700 mV, which was chosen to correlate with the built-in potential of these devices. More detailed information is included below. FIG. 10B shows photo-CELIV transients of a (PBDTTT-C:PBDTT-DPP):PC70BM ternary and its reference binary systems. FIG. 10C shows photo-CELIV transients of a (P3HT:PBDTT-DPP):PC70BM ternary and its reference binary systems. FIG. 10D shows photo-CELIV transients of a (PBDTTT-C:PBDTT-DPP):PC70BM ternary BHJ device, as a function of different extracting voltages. FIG. 10E shows photo-CELIV transients of a (P3HT:PBDTT-DPP):PC70BM ternary BHJ device, as a function of different extracting voltages.

The effective charge carrier mobility can be estimated based on the following equation^{30, 31}:

$$μ = \frac{2 {d}^{2}}{3 {At}_{max}^{2} [ 1 + 0.36 \frac{Δ j}{j ( 0 )} ]} if Δ j \leq j ( 0 ) \qquad ( Equation 1 )$$

where μ is the mobility, d is the thickness of the BHJ active layer, tₘₐₓ is the time when the extracted current reaches its maximum value, A is the slope of the extraction voltage ramp, j(0) is the dark capacitive current, and Δj is the transient current peak height, as shown in FIG. 10A.

The mobility values of the effective charge carriers in the (PBDTTT-C:PBDTT-DPP=1:1):PC₇₀BM ternary system was 8×10⁻⁵ cm²/V sec, which was comparable to a PBDTTT-C:PC₇₀BM device (7×10⁻⁵ cm²/V sec) and a PBDTT-DPP:PC₇₀BM device (1.0×10⁻⁴ cm²/V sec). On the other hand, in devices made from the incompatible ternary BHJ system containing P3HT and PBDTT-DPP, Δj was much less than for its reference binary BHJ solar cells, clearly indicating that many fewer free carriers were extracted under the same condition. The effective carrier mobility value of 2×10⁻⁵ cm²/V sec was estimated from the first photo-CELIV transient peak, which was ˜45 times lower than the P3HT:PC₇₀BM device value of 9×10⁻⁴ cm²/V sec and ˜5 times lower than the PBDTT-DPP:PC₇₀BM device value of 1×10⁴ cm²/V sec. FIGS. 10D and 10E show the photo-CELIV transients of the well-performed and poorly-performed ternary BJH devices as a function of extracting voltage, and the capacitive current j₀ was subtracted to better concentrate on the dynamics of photo-induced carriers. We find that there is only one peak in the (PBDTTT-C:PBDTT-DPP=1:1):PC70BM ternary BHJ device, while two characteristic maxima were observed in the (P3HT:PBDTT-DPP=1:1):PC₇₀BM ternary BHJ device. The presence of two peaks in the current transient signifies unbalanced charge transportation of holes and electrons^{32, 33, 34} which has been observed in some of the unfavorable OPV devices^{32, 34} Generally, the misbalance of two carriers will lead to low fill factor of the photovoltaic device^{35, 36}. Overall, the effective charge carrier mobility was observed to dramatically decrease and become unbalanced in the (P3HT:PBDTT-DPP):PC₇₀BM ternary BHJ system compared to its binary components, but remained relatively unchanged in the (PBDTTT-C:PBDTT-DPP):PC₇₀BM ternary system. These results indicate that the effective carrier mobility could be a useful indicator to test the structural and morphological compatibility of polymers for potential use in high performance ternary BHJ systems.

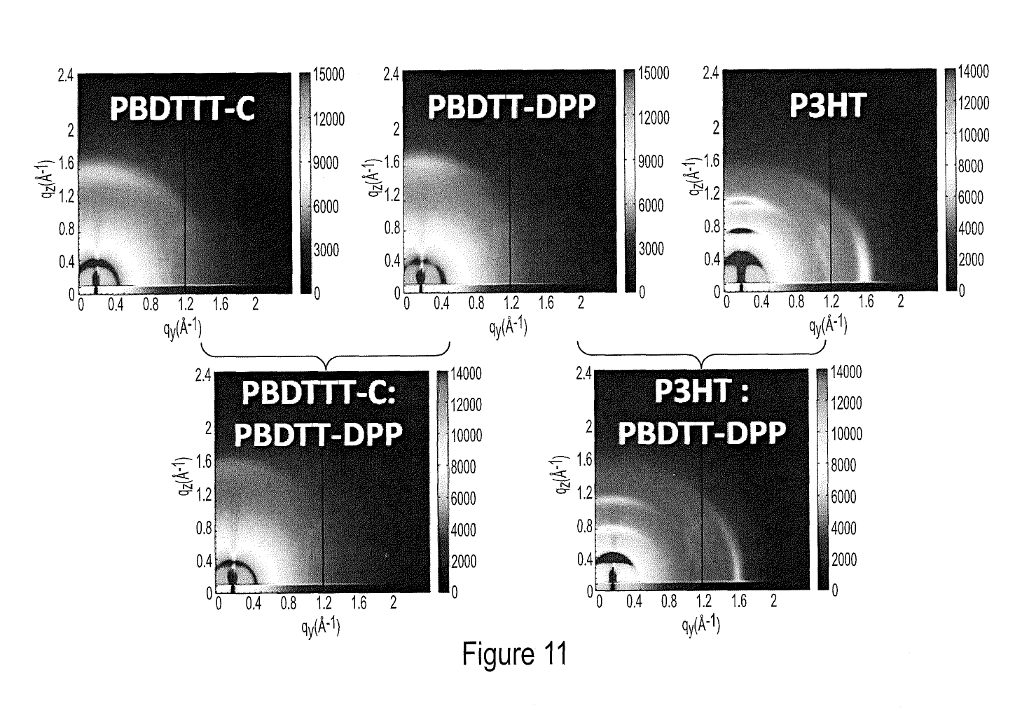

To correlate the electronic properties of the ternary blending with structural information such as molecular orientation, intermolecular distance, and crystallite sizes, Grazing Incidence Wide Angle X-ray Scattering (GIWAXS) was performed. The 2D GIWAXS patterns for each individual polymer and their blends are shown in FIG. 11. All thin film samples were measured on an Si substrate (with a naturally formed SiO₂ surface) pre-coated with 30 nm of PEDOT:PSS. The thicknesses of the polymer and polymer blend layers were each approximately 100 nm. Two distinct out-of-plane peaks appear in the PBDTTT-C and PBDTT-DPP films, with q_{z}=1.54±0.06 Å⁻¹ and q_{z}=1.59±0.06 Å⁻¹, which are associated with the π-π stacking distance of 4.1±0.2 Å and 4.0±0.2 Å, respectively. This indicates that the π-π stacking direction is perpendicular to the substrate in PBDTTT-C and PBDTT-DPP films, and that these two polymers thus prefer a “face-on” orientation. After PBDTTT-C and PBDTT-DPP were blended together, this π-π stacking peak still appeared in the 2D GIWAXS pattern with q_{z}=1.53±0.06 Å⁻¹, which suggests that the preferred molecular orientation with the substrate remains unchanged in the blended film.

The π-π stacking coherence length can also be estimated using the full width at half-maximum (fwhm) of the scattering peaks based on the Scherrer equation^{37,38}:

$$L = \frac{2 \cdot {( ln 2 / π )}^{1 / 2} \cdot 2 π}{Δ q} \\ Δ q = {[ {( Δ q )}_{experiment}^{2} - {( Δ q )}_{resolution}^{2} ]}^{1 / 2} \qquad ( Equation 2 )$$

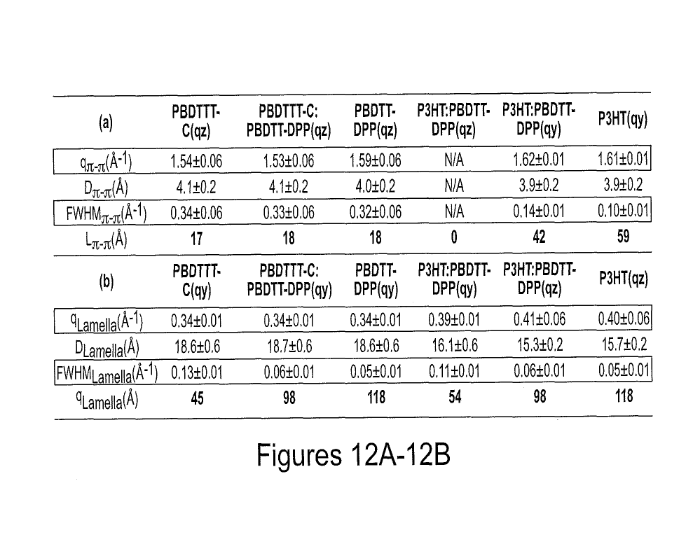

We found that the coherence length along the π-π stacking direction for PBDTTT-C, PBDTTT-C:PBDTT-DPP blend, and PBDTT-DPP are 17 Å, 17 Å, and 18 Å, respectively, which corresponds to roughly four stacked molecules in all the three samples. These results indicate a general retention of π-π coherence length (Lπ-π) after the two “face-on” polymers are mixed, which is a promising sign of their ability to form compact films without disrupting the morphology and stacking structure of the other polymer. On the other hand, the π-π stacking peak in pure P3HT films is manifestly shown in the in-plane axis, with q_{y}=1.61±0.01 Å⁻¹ indicating a strong preference for the “edge-on” orientation. Three distinct peaks arising from the (100), (200), and (300) Bragg diffraction peaks corresponding to periodic P3HT lamellae in the out-of-plane direction were also observed, which have been reported in previous structural studies of P3HT films¹⁷. By blending the “face-on” PBDTT-DPP with the “edge-on” P3HT, no peaks corresponding to π-π stacking could be observed in the out-of-plane direction, suggesting that the π-π stacking of the polymer PBDTT-DPP was suppressed in the mixtures with P3HT. Due to the strong crystallinity of P3HT, the in-plane π-π stacking peak is still present, however, the π-π stacking coherence length (L_{π-π}) decreased from 59 Å to 42 Å, corresponding to a significantly reduced number of π-π stacked molecules from ˜15 to ˜10. The quantitative information obtained from the 2-D GIWAXS patterns is summarized in the table shown in FIG. 12A.

The table shown in FIG. 12B summarizes the quantitative molecular packing information in the (100) direction, which indicates the intermolecular lamella distance and aggregation length along this direction. The lamella distance remained unchanged after PBDTTT-C and PBDTT-DPP were blended. The crystalline (aggregation) length (Lₗₐₘₑₗₗₐ) is around 98 Å, and it was in between that of the pristine PBDTTT-C (45 Å) and PBDTT-DPP (118 Å) films. However, the crystalline length degraded in the P3HT:PBDTT-DPP blending system compared to its two reference systems, especially for the less crystalline polymer PBDTT-DPP. The in-plane crystalline length (for PBDTT-DPP) deceased from 118 Å to 54 Å, and the out-of-plane crystalline length (for P3HT) decreased from 118 Å to 98 Å. The 2-D GIWAXS signifies that both i-n stacking and intermolecular lamella interaction remain moderately unaffected in the PBDTTT-C:PBDTT-DPP blending system, while both of them are adversely affected in the incompatible P3HT:PBDTT-DPP blending system.

The non-conjugated polymer side chain is largely insulating, while the conjugated backbone is conductive. When two polymers with different molecular orientations are mixed, as in the P3HT:PBDTT-DPP blended system, the non-conductive side chain and the conductive conjugated backbone are likely to be stacked with one another in an alternating pattern. This reduces the crystalline length, disrupts long range charge transport and lowers the charge carrier mobility of the blended film. The scenario is illustrated in FIG. 5. The charge carrier mobility in semiconducting polymers has been proven to be correlated with the preferred orientation of π-π stacking, the π-π stacking coherence length and the degree of polymer aggregation (or crystallinity)³⁹⁻⁴³. All of these structural characteristics remain relatively unchanged in the well-performed ternary system, while the confrontational effects are observed in the poorly-performed ternary solar cell system.

Taken together, the GIWAXS results explain on a molecular scale the dramatically different electronic and photovoltaic device performance of the two ternary BHJ systems. The blending of the two “face-on” polymers PBDTTT-C and PBDTT-DPP with the identical BDT unit doesn't introduce significant interference to their molecular stacking preferences, and crystallite size is also maintained. Therefore, the electronic transport properties are preserved in the ternary blends, and PBDTTT-C and PBDTT-DPP are able to work independently and contribute to photovoltaic device performance more like two parallel cells. Recently, Brabec et al. reported a ternary BHJ solar cell with P3HT blended with Si-PCPDTBT that achieved a broadened photo current response as well as an acceptable fill factor⁴⁴, suggesting a relatively good compatibility between these two materials. Interestingly, Si-PCPDTBT has “edge-on” orientation and fairly good crystallinity^{45, 46} similar to P3HT. This result also supports our model that the matching of molecular packing is one of the key factors governing the compatibility of donor materials.

In the incompatible ternary system of P3HT and PBDTT-DPP, the stacking structure of the less crystalline polymer PBDTT-DPP is significantly disrupted, as evidenced by the disappearance of the out-of-plane π-π stacking peak in blended films as well as the decreased in-plane lamella aggregation length. The π-π stacking of the more crystalline polymer P3HT is also affected, mainly indicated by the reduced π-π stacking coherence length. Thus, the charge transport properties are dramatically reduced in this ternary blend, and the photovoltaic performance suffers even though P3HT and PBDTT-DPP have highly complementary absorption spectra. With this in mind, we can infer that molecules with complementary absorption ranges and good structural compatibility, such as similar crystallinity and molecular orientation, are potential candidates to achieve high performance ternary BHJ solar cells. Structural compatibility may also be linked to polymers with similar molecular groups, such as the shared BDT unit in the backbones of PBDTTT-C and PBDTT-DPP.

Bearing in mind the knowledge obtained from the ternary BHJ photovoltaic systems discussed above, we have further applied this model to separate ternary blends containing PTB7 and PBDTT-SeDPP. PTB7 has a similar molecular structure and “edge-on” molecular orientation to that of PBDTTT-C, and its absorption edge is blue shifted by roughly 10 nm, but the overall photovoltaic performance is better^{10, 20}. PBDTT-SeDPP is an improved form of PBDTT-DPP, with its absorption edge red shifted by 50 nm to roughly a 900 nm onset²². These properties of PTB7 and PBDTT-SeDPP are expected to make them even better ternary blend polymer solar cell systems.

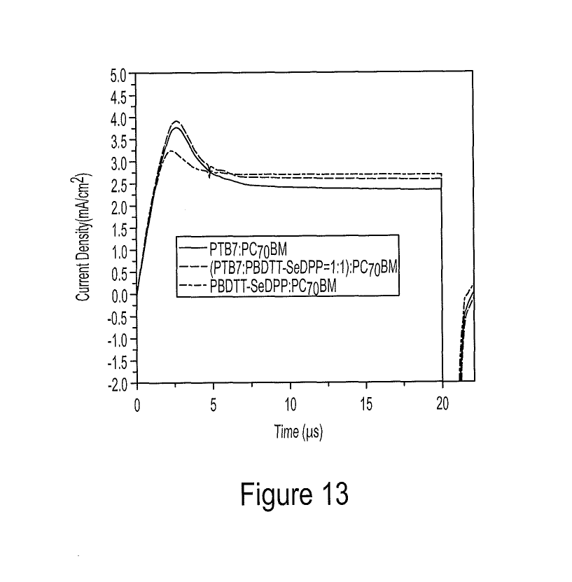

The ternary (PTB7:PBDTT-SeDPP=1:1):PC₇₀BM device produced an efficiency of 8.7%, which is significantly higher than that of device made from its individual donor materials. For comparison, the PTB7:PC₇₀BM binary BHJ solar cell produced 7.2% efficiency, and the PBDTT-SeDPP:PC₇₀BM binary BHJ solar cell achieved 7.2% as well (both binary cells used DCB as a solvent), which gives the blended donor devices a 21% relative enhancement in PCE with respect to the binary cells, as shown in FIGS. 6A-6D. The effective charge carrier mobility values were also calculated by the photo-CELIV method. FIG. 13 shows a plot of a photo-CELIV measurement of the (PTB7:PBDTT-DPP):PC₇₀BM ternary BHJ solar cell system. All the devices have the same structure of ITO/PEDOT:PSS/(Polymer or Polymer blend):PC₇₀BM/Ca/Al. The BHJ active layer thicknesses are 95 nm, 115 nm and 100 nm for PTB7:PC₇₀BM, (PTB7:PBDTT-SeDPP=1:1):PC₇₀BM and PBDTT-SeDPP:PC₇₀BM, respectively. The charge carrier mobility was dominated by the tₘₐₓ values, which were comparable in all the three types of devices. The carrier mobility of the ternary BHJ system remained comparable to the reference binary systems, ranging from 1×10⁻⁴ to 2×10⁻⁴ cm²/V sec.

The ternary BHJ photovoltaic outperformed each binary BHJ photovoltaic at three different polymer blending ratios—25%, 50% and 75% PBDTT-SeDPP, as shown in the table in FIG. 7. The D/A ratio in all of the devices was 1:2. The ternary BHJ photovoltaic device may be further improved by optimizing the D/A ratio and by changing the solvent or using a co-solvent system, since the optimized solvents for PTB7 and PBDTT-SeDPP are different, as mentioned in the previous section.

Since both the PBDTTT-C:PBDTT-DPP and PTB7:PBDTT-SeDPP systems appear to provide good structural compatibility and device performance, it may enable an efficient BHJ polymer solar cell comprising these four different donor polymers. Indeed, preliminary result from a four-donor BHJ solar cell presented the very reasonable performance of 7.8% efficiency, with EQE values close to those of the constituent polymers, as shown in FIGS. 6B and 6D. The results conceptually indicate that mixing two or even more donor materials into one BHJ is possible as long as they exhibit sufficient structural compatibility.

Another important factor that determines the overall efficiency of multiple donor BHJ solar cells is the open circuit voltage (Voc). The Voc's of the multiple donor BHJ systems fell within the Voc values of the binary BHJ solar cells, which to certain extent agrees with the results reported by Thompson et al., in which tunable Voc was observed in their ternary systems^{47, 48}. Within the donor ratios in our ternary solar cell systems (between 3:1 to 1:3), the majority of the good ternary devices has Voc closer to the lower Voc of two binary cells, except for the case of the PBDTTT-C:PBDTT-DPP 1:3 ratio device, where Voc (0.73 V) is closer to that in the higher Voc cell (PBDTT-DPP:PCBM—0.74 V). This tunable effect may be helpful for designing ternary solar cell systems with improved Voc as well.

In summary, we report the structural, electronic, and photovoltaic characteristics of several ternary BHJ solar cell systems. Two successful ternary BHJ solar cells have been demonstrated, and the most efficient devices achieved 8.7% PCE. By comparing the successful and unsuccessful multiple donor systems, a relationship between device performance and the molecular structure of the donor materials has been established. We conclude that structural compatibility is the key factor for achieving high performance in multiple donor BHJ polymer solar cells. Indications of compatibility between polymers include preferred molecular orientation, crystallite size, and so on. From a synthetic perspective, the requirement for good molecular compatibility between polymers appears most likely to be satisfied by materials with similar structures, such as shared monomer units along the polymer backbone. This work not only proves the feasibility of producing highly efficient BHJ polymer solar cells that incorporate more than one donor material, but also provides guidelines for matching existing materials and designing new ones explicitly for this purpose.

The materials used according to an embodiment of the invention include the following. P3HT was purchased from Rieke Metals. PC₇₀BM was purchased from Nano-C. PTB7 and PBDTTT-C was purchased from 1-Material Inc. and Solarmer Materials Inc., respectively. These materials were used as received without further purification. PBDTT-DPP and PBDTT-SeDPP were synthesized in-house, according to recipes reported in previous papers^{18, 22}. The polymers used in this project were all from the same batch in order to ensure a fair comparison between experimental and control devices.

The device fabrication and measurements according to an embodiment of the invention are described herein. Photovoltaic devices were fabricated on indium tin oxide (ITO) coated glass substrates that served as the anode. The ITO substrates were ultrasonically cleaned in detergent, deionized water, acetone, and isopropanol. A layer of 30 nm PEDOT:PSS (poly(3,4-ethylenedioxythiophene):poly(styrene sulfonate)) (Baytron P VPAI 4083, Germany) was spin-coated onto the ITO substrate and was dried in air at 120° C. for 10 minutes. Polymer/PC₇₀BM or Polymer blend/PC₇₀BM were dissolved in 1,2-dichlorobenzene (O-DCB) and were spin coated on top of the PEDOT layer. Finally, the Ca/Al cathode (100 nm) was vacuum evaporated onto the annealed photoactive layer.

The reference P3HT:PC70BM solar cells were spin coated at 800 rpm with a 1:1 D/A ratio followed by a “slow growth” method, as reported in the literature⁹. The thickness was around 210 nm. For both the (PBDTTT-C:PBDTT-DPP):PC₇₀BM and (PTB7:PBDTT-SeDPP):PC₇₀BM ternary BHJ solar cell systems, the D/A ratio was kept at 1:2, and each was spin cast from (DCB+3% DIO) solutions. The optimized thicknesses for PBDTTT-C:PC₇₀BM, (PBDTTT-C:PBDTT-DPP=1:1):PC70BM and PBDTT-DPP:PC₇₀BM solar cells were 110 nm, 130 nm, and 105 nm, respectively. In the (PTB7:PBDTT-SeDPP):PC₇₀BM ternary BHJ solar cell system, the optimized thicknesses for PTB7:PC₇₀BM, (PTB7:PBDTT-SeDPP=1:1):PC₇₀BM and PBDTT-DPP:PC₇₀BM solar cells were 95 nm, 115 nm, and 100 nm, respectively. For the four-donor BHJ solar cell, the active layer was spin-cast from the combined solution of (PBDTTT-C:PBDTT-DPP=1:1):PC₇₀BM and (PTB7:PBDTT-SeDPP=1:1):PC70BM with a 1:1 vol. ratio, so that the D/A ratio was 1:2, and the device thickness was roughly 120 nm.

The effective area of the devices was 0.1 cm². The J-V measurements of the photovoltaic devices were conducted using a Keithley 236 Source-Measure unit. A xenon lamp with an AM1.5G filter (NEWPORT) simulated 1 sun conditions, and the light intensity at the sample was 100 mW/cm², calibrated with a Mono-Si photodiode with KG-5 color filter. The reference diode is traceable to NREL certification. EQE measurements were conducted with an integrated system from EnliTech, Taiwan.

Photo-induced charge carrier extraction in a linearly increasing voltage (Photo-CELIV) measurements were performed. Photo-CELIV measurements were used to determine the charge carrier mobility in the single and multiple donor BHJ solar cells. The device structure was ITO/PEDOT:PSS/Polymer or Polymer Blend:PC71BM/Ca/Al. A 590 nm dye (Rhodamine Chloride 590) laser pumped by a nitrogen laser (LSI VSL-337ND-S) was used as the excitation source, with pulse energy and pulse width values of 3 mJ/cm² and 4 ns, respectively. The transient current was first amplified by a current amplifier (Femto DHPCA-100), then a preamplifier (SR SSR445A), and finally recorded by a digital oscilloscope (Tektronix DPO 4104). In FIGS. 10A and 10B, the maximum value of the extracting voltage was 3.0V, and the time period was 20 μs. For PBDTTT-C:PC₇₀BM, (PBDTTT-C:PBDTT-DPP=1:1):PC70BM and (PBDTT-DPP:PC₇₀BM), the tₘₐₓ values were 2.8 μs, 3.0 μs, and 2.3 μs, and the BHJ active layer thicknesses were 110 nm, 130 nm and 105 nm respectively. For P3HT:PC₇₀BM, tₘₐₓ was 1.8 s, and the thickness was 210 nm. For (P3HT:PBDTT-DPP=1:1):PC₇₀BM with a 110 nm BHJ device, tₘₐₓ for the first peak was 5.1 μs.

### Further Examples

Broadening the absorption bandwidth of polymer solar cell by incorporating multiple absorber donors into the bulk-heterojunction (BHJ) active layer is a straightforward way of resolving the narrow absorption of organic semiconductors. However, this leads to a much more complicated system, and previous efforts have met with limited success. In this manuscript, several dual-donor and multi-donor BHJ polymer solar cells based on a material pool with different absorption ranges and preferred molecular structures/orientations were studied. The comparison study shows clearly that compatible polymer donors can coexist harmoniously, but the mixing of incompatible polymers can lead to severe molecular disorder and limit the device performance. These results provide guidance for the general use of multi-donor BHJ to overcome the absorption limitation, and for achieving both high performance and fabrication simplicity for organic solar cells.

Polymer photovoltaic cells have shown great potential as a means to harvest solar energy in a highly processable and cost-effective manner¹⁻⁵. Typical organic solar cells consist of a mixture of a polymer (or organic small molecule) donor and a C-60 derivative acceptor as the photo-active layer. In bulk-heterojunction (BHJ) organic solar cells, the absorbed incident photons generate tightly bound electron-hole pairs, which are then dissociated into electrons and holes at the nearby donor/acceptor interface. The electrons and holes are then transported to their respective electrodes⁶⁸.

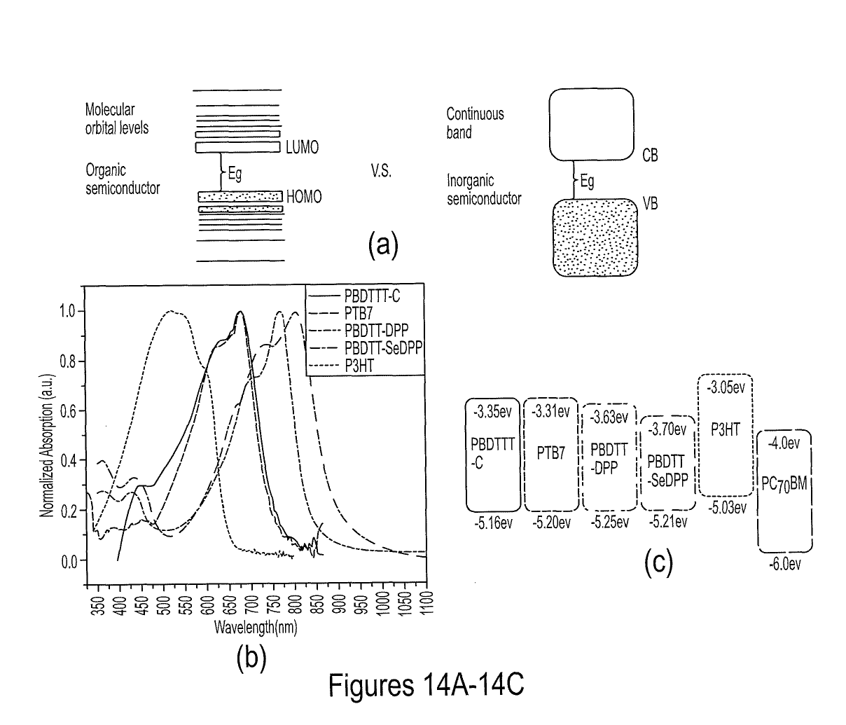

Research efforts in the last decade or so have significantly improved organic solar cell performance⁹⁻¹⁴, and power conversion efficiency (PCE) values beyond 10% have recently been achieved⁵⁻¹⁶. Over the years, significant research efforts have been put into developing low band gap polymers to extend the absorption and harvest more solar energy. Nevertheless, unlike the continuous band structure of inorganic semiconductors like Si, the molecular orbital energy level of organic or polymeric semiconductors is narrow, which makes it challenging to obtain the panchromatic absorption coverage with a single organic semiconductor. FIG. 14A shows a general schematic of the band structure of organic/polymeric and inorganic semiconductors. FIGS. 14B and 14C show absorption spectra and energy band diagrams, respectively, of the material pool according to an embodiment of the invention. The narrow molecular orbital energy level of organic or polymeric semiconductors is one of the reasons that polymer solar cells invariably exhibit low short circuit current (Jsc), compared with commercial inorganic solar cells. In addition, it has been very difficult to achieve as high an external quantum efficiency (EQE) in low band gap polymer systems (E_{g}<1.4 eV) as in traditional polymer systems such as poly(3-hexyl thiophene) (P3HT) with reported EQE values of over 70%¹⁷. Even with their imperfect characteristics, this rich set of low band gap polymers are very valuable in improving state-of-the-art polymer solar cells if OPV devices are designed with multiple compatible polymers to expand the absorption range while at the same time maintaining other key parameters, such as open circuit voltage (Voc) and fill factor (FF).

Unfortunately, very few successful ternary BHJ polymer photovoltaic cell structures have been reported that surpass the efficiency of their corresponding binary BHJ devices²³. The ideal scenario is that the multiple polymers will work independently like parallel-connected devices, which will lead to a Jsc approximately equal to the summation of the two independent cells. However, in reality the interactions between the two polymers are inevitable due to their different chemical and physical natures. These unfavorable interactions might function as “morphological traps” and recombination centers, which lead to reduced photovoltaic performance in the complex multiple donor BHJ system. Recent progress in the development of new photovoltaic materials has made available a wide pool of high performance donor polymers with different absorption ranges that have been widely used in OPV research, for example: poly[4,8-bis-substituted-benzo[1,2-b:4,5-b0]dithiophene-2,6-diyl-alt-4-substituted-thieno[3,4-b]thiophene-2,6-diyl](PBDTTT-C) with E_{g}=1.60 eV; poly{2,6-4,8-di(5ethylhexylthienyl) benzo[1,2-b;3,4-b]dithiophene-alt-5-dibutyloctyl-3,6-bis(5-bromothiophen-2-yl)pyrrolo[3,4-c]pyrrole-1,4-dione} (PBDTT-DPP) with E_{g}=1.46 eV; poly{4,6-(2-ethylhexyl-3-fluorothieno[3,4-b]thiophene-2-carboxylate)alt-2,6(4,8-bis(2-ethylhexyloxy)benzo[1,2-b:4,5-b]dithiophene)} (PTB7) with E_{g}=1.62 eV; (poly{2,6′-4,8-di(5-ethylhexylthienyl) benzo[1,2-b;3,4-b]dithiophene-alt-2,5-bis(2-butyloctyl)-3,6-bis(selenophene-2-yl)pyrrolo[3,4-c]pyrrole-1,4-dione} (PBDTT-SeDPP) with Eg=1.38 eV and P3HT with E_{g}=1.90 eV^{10, 18, 19, 20, 21, 22}. It is well known that different high performance polymers have their own preferred morphologies in the active layer, including molecular orientation with respect to the substrate, crystallinity, domain size and so on. For instance, regio-regular P3HT tends to form edge-on lamellae in P3HT:PCBM films and exhibits much higher crystallinity compared with most other donor polymers, both of which are associated with its high photovoltaic performance^{17, 24}. On the other hand, in many of the newer high performance donor polymers such as thienothiophene (TT) and benzo-dithiophene (BDT), BDT and N-alkylthieno[3,4-c]pyrrole-4,6-dione (TPD) based co-polymers^{19, 25, 26, 27}, the preferred orientation to the substrate is face-on^{19, 27, 28}. This packing orientation is considered to be more advantageous to hole transportation in the vertical diode configuration, such as photovoltaic^{28, 29}. In addition, most of them show significantly more amorphous character in their films than P3HT²⁸. We report herein that two blended polymers with compatible physical natures (including molecular orientation, crystallinity and domain structure, etc.,) lead to less interference when forming the morphology of the bulk heterojunction active layers. Intuitively, the compatible physical property might strongly relate with the similarity of the chemical structures.

The ternary polymer blend/fullerene systems studied here each have both a high band gap polymer and a low band gap polymer in order to cover a boarder section of the solar spectrum. FIGS. 14 and 2A show the model materials according to an embodiment of the invention, all of which have previously been reported as high performance photovoltaic materials featuring different absorption ranges and different molecular stacking preferences. For example, PBDTTT-C and P3HT both have demonstrated high EQE and PCE values, but one prefers an edge-on and the other one prefers a face-on orientation in OPV absorber films. These photovoltaic materials have been reported with good device performance, but substantially different processing methods. Choosing a solvent that is compatible with each material represents a particularly difficult challenge. PBDTTT-C and PTB7 generally work best when deposited from chlorobenzene (CB) with efficiencies of 6.58% and 7.4% respectively, with their performance slightly reduced when processed in dichlorobenzene (DCB)^{10, 20}. However, polymer PBDTT-DPP and PBDTT-SeDPP are not sufficiently soluble in CB to form uniform films, so they are normally processed from DCB^{18, 22}. To balance these ideal processing differences and set up an appropriate baseline, all the BHJ devices discussed here are fabricated using DCB as a solvent.

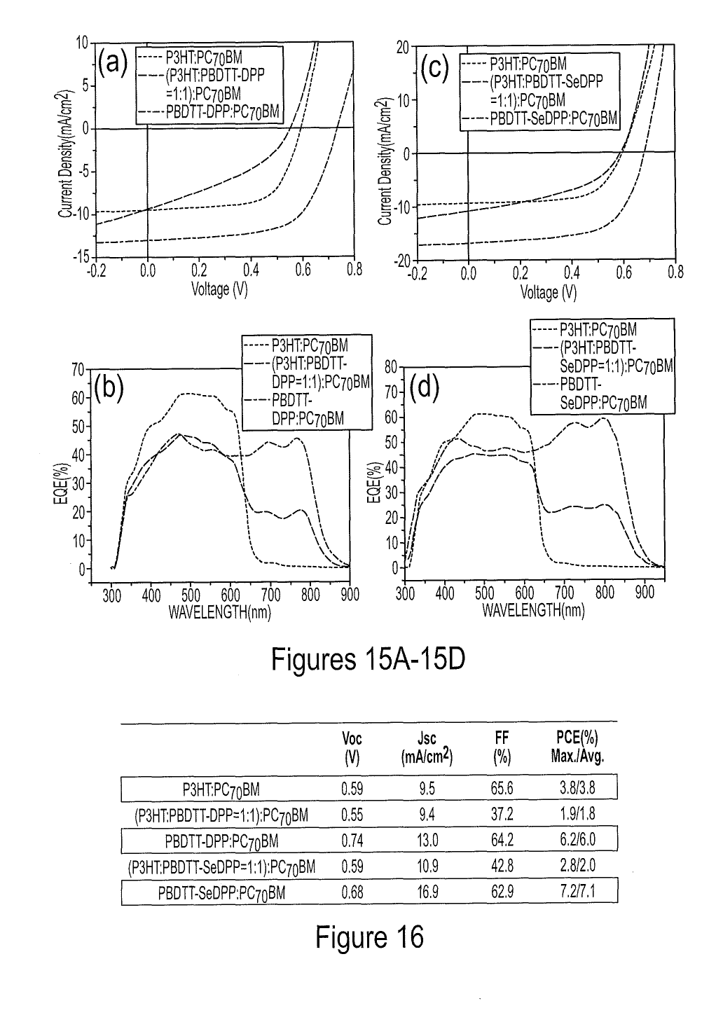

In the material pool shown in FIGS. 14A-C, RR-P3HT has an absorption edge around 650 nm, and is expected to be spectrally matched to PBDTT-DPP and PBDTT-SeDPP. FIG. 15A shows a J-V curve of the (P3HT:PBDTT-DPP):PC70BM ternary BHJ solar cell system measured under one sun conditions (100 mW/cm²). FIG. 15B shows an EQE measurement of the (P3HT:PBDTT-DPP):PC70BM ternary BHJ solar cell system. FIG. 15C shows a J-V curve of the (P3HT:PBDTT-SeDPP):PC70BM ternary BHJ solar cell system measured under one sun conditions (100 mW/cm²). FIG. 15D shows an EQE measurement of the (P3HT:PBDTT-SeDPP):PC70BM ternary BHJ solar cell system. The devices with blended polymers present a much broader photocurrent response, as shown in FIGS. 15A-15D, but do not produce an overall enhancement of photocurrent due to significant reductions in EQE. Additionally, the fill factor decreased markedly from ˜65% to less than 40% in the mixed polymer device. In other word, the addition of absorption doesn't translate into the addition of photovoltaic device performance. These results are not surprising, as photovoltaic device employing blended donors have produced even worse performance in many circumstances. Results obtained from other low band gap polymers PBDTT-SeDPP, and RR-P3HT ternary BHJ solar cells are also summarized in FIGS. 15A-15D, and the device performance of these two unsuccessful ternary systems are summarized in the table displayed in FIG. 16.

Our strategy to improve the performance of multiple polymer systems is to optimize the compatibility of the individual donor materials, allowing them to work more like independent cells. The molecular compatibility of two or more polymers can be intuitively expected to correlate with various structural similarities. In the pool of available model materials, PBDTTT-C, PBDTT-DPP, PTB7, and PBDTT-SeDPP, all have the rigid, planar benzodithiophene (BDT) unit in their backbone. Face-on with respect to the substrate is the preferred orientation for these polymers in deposited active layers.

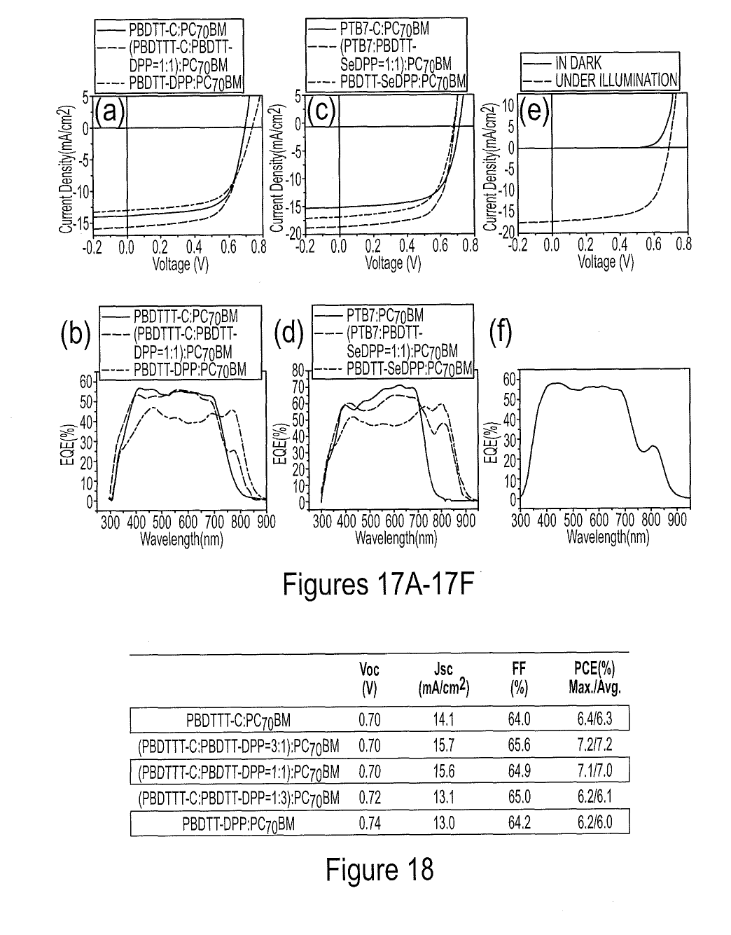

Taking both molecular compatibility and absorption characteristics into consideration, a ternary blending system using PBDTTT-C:PBDTT-DPP as donors was studied. FIGS. 17A and 17B show the device results of the (PBDTTT-C:PBDTT-DPP):PC₇₀BM ternary BHJ solar cells, along with their two binary BHJ solar cells as control devices. FIG. 17A shows a J-V curve of the (PBDTTT-C:PBDTT-DPP):PC70BM ternary BHJ solar cell system measured under one sun conditions (100 mW/cm²). FIG. 17B shows an EQE measurement of the (PBDTTT-C:PBDTT-DPP):PC70BM ternary BHJ solar cell system. Individual PBDTTT-C:PC₇₀BM and PBDTT-DPP:PC₇₀BM solar cells have optimized power conversion efficiency values of 6.4% and 6.2%, respectively. The EQE spectrum of the ternary BHJ device of (PBDTTT-C:PBDTT-DPP=1:1):PC₇₀BM distinctively shows the combined photoresponse of both polymer donors, and as a result the overall photocurrent increases to 15.7 mA/cm², surpassing each binary reference system. Surprisingly, the ternary BHJ photovoltaic devices still maintain a very high FF of 65%. The optimized ternary solar cells outperform the reference binary cells at certain blending ratios, as shown in the table in FIG. 18, specifically 3:1 and 1:1.

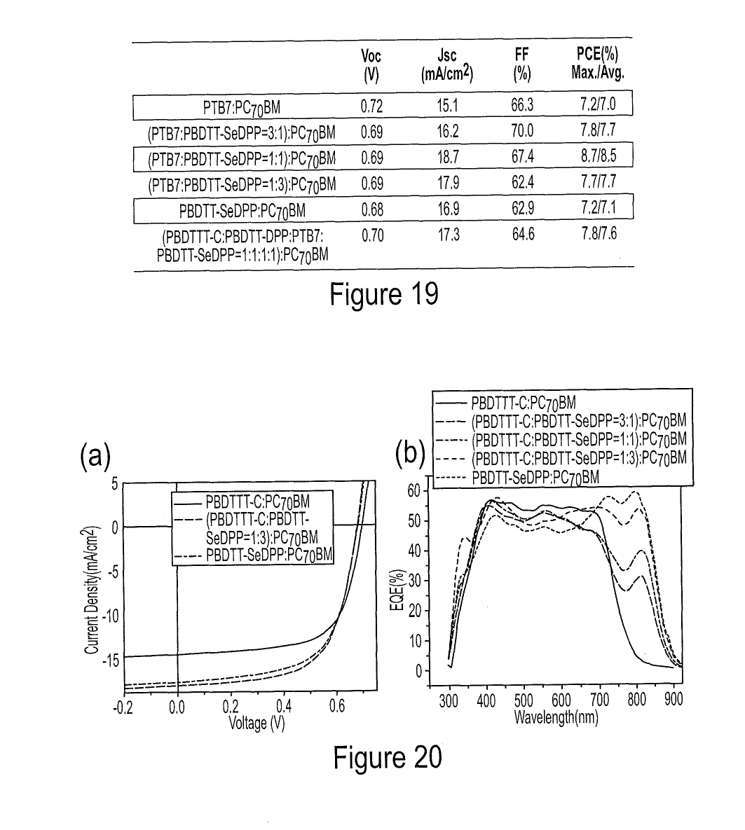

Bearing in mind the knowledge obtained from the ternary BHJ photovoltaic systems discussed above, we have further applied this model to separate ternary blends containing PTB7 and PBDTT-SeDPP. PTB7 has a similar molecular structure and “face-on” molecular orientation to that of PBDTTT-C, and its absorption edge is blue shifted by roughly 10 nm, but the overall photovoltaic performance is better^{10, 20}. PBDTT-SeDPP is an improved form of PBDTT-DPP, with its absorption edge red shifted by 50 nm to a roughly 900 nm onset²². These properties of PTB7 and PBDTT-SeDPP will enable us to observe the effect more clearly (less absorption overlap) and are expected to make them even better ternary blend polymer solar cell system. The ternary (PTB7:PBDTT-SeDPP=1:1):PC₇₀BM device produced an efficiency of 8.7%, which is significantly higher than that of those made from its individual donor materials. For comparison, the PTB7:PC₇₀BM binary BHJ solar cell produced 7.2% efficiency, and the PBDTT-SeDPP:PC₇₀BM binary BHJ solar cell achieved 7.2% as well (both binary cells used DCB as solvent), which gave the blended donor devices a 21% relative enhancement in PCE with respect to the binary cell. This is shown in FIGS. 17C and 17D. FIG. 17C shows a J-V curve of the (PTB7:PBDTT-SeDPP):PC70BM ternary BHJ solar cell system measured under one sun conditions (100 mW/cm²). FIG. 17D shows an EQE measurement of the (PTB7:PBDTT-SeDPP):PC70BM ternary BHJ solar cell system. The table in FIG. 19 shows the device performance of the (PTB7:PBDTT-SeDPP):PC70BM ternary BHJ solar cell system. The ternary BHJ photovoltaic outperformed each binary BHJ photovoltaic at three different polymer blending ratios—25%, 50% and 75% PBDTT-SeDPP, as shown in FIG. 19. The D/A ratio in all of the devices was 1:2. It worth mentioning that the ternary BHJ photovoltaic device may be further improved by optimizing the D/A ratio and by changing the solvent or using a co-solvent system, since the optimized solvents for PTB7 and PBDTT-SeDPP are different as mentioned in the previous section. Since both the PBDTTT-C:PBDTT-DPP and PTB7:PBDTT-SeDPP systems appear to provide good structural compatibility and device performance, it may enable an efficient BHJ polymer solar cell with any two blended polymers.

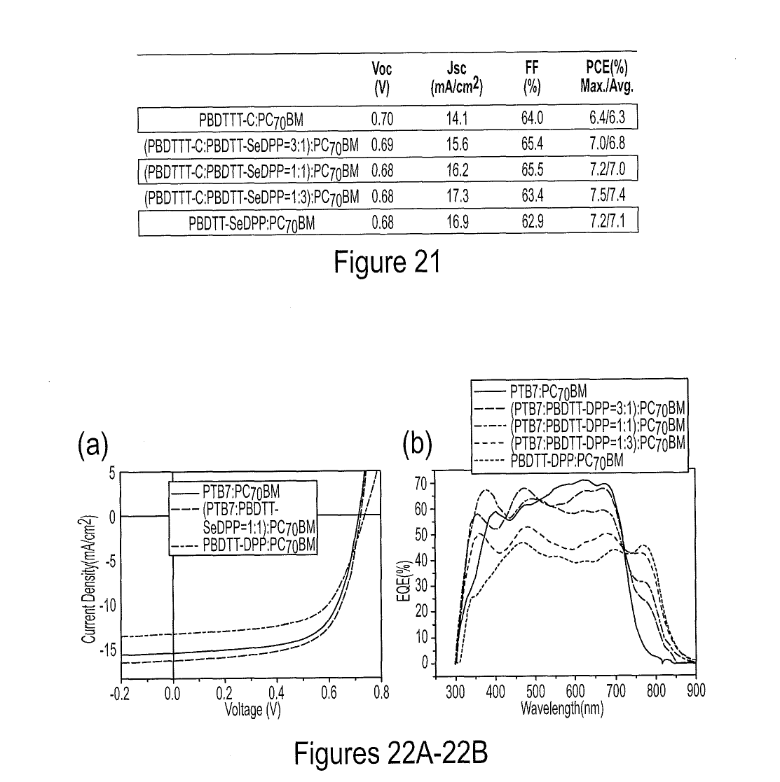

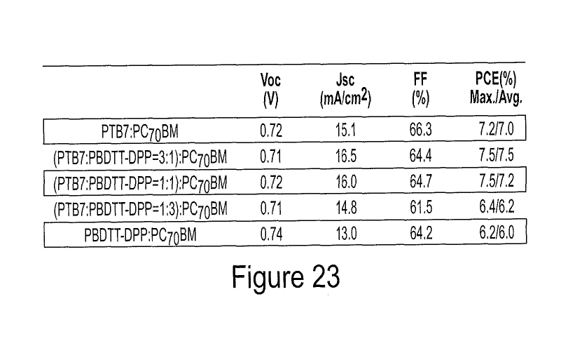

FIG. 20A shows a J-V curve of the (PBDTTT-C:PBDTT-SeDPP):PC70BM ternary BHJ solar cell system measured under one sun conditions (100 mW/cm²). FIG. 20B shows an EQE measurement of the (PBDTTT-C:PBDTT-SeDPP):PC70BM ternary BHJ solar cell system. The table in FIG. 21 shows the device performance of (PBDTTT-C:PBDTT-SeDPP):PC70BM BHJ ternary solar cell systems. Indeed, the results show that PBDTTT-C:PBDTT-SeDPP ternary BHJ solar cells deliver reasonably enhanced device efficiency as well. FIG. 22A shows a J-V curve of the (PTB7:PBDTT-DPP):PC₇₀BM ternary BHJ solar cell system measured under one sun conditions (100 mW/cm²). FIG. 22B shows an EQE measurement of the (PTB7:PBDTT-DPP):PC₇₀BM ternary BHJ solar cell system. The table in FIG. 23 shows device performance of (PTB7:PBDTT-DPP):PC70BM BHJ ternary solar cell systems. The results show that PBT7:PBDTT-DPP ternary BHJ solar cells also deliver reasonably enhanced device efficiency.

Furthermore, a four-donor BHJ solar cell presented the very reasonable performance of 7.8% efficiency, with EQE values close to those of the constituent polymers. This is shown in FIGS. 17E and 17F. FIG. 17E shows a J-V curve of a (PBDTTT-C:PBDTT-DPP:PTB7:PBDTT-SeDPP):PC70BM multi-donor BHJ measured under one sun (100 mW/cm²) and dark conditions. FIG. 17F shows an EQE measurement of the multi-donor system. The results conceptually indicate that by mixing two or even more structurally compatible donor materials into one BHJ it is possible to achieve high efficiency multi donor solar cell devices.

Clearly, the dramatically different results of different dual polymer BHJ systems infer that structurally compatible polymers can efficiently coexist, while using structurally incompatible polymers, such as P3HT and PBDTT-DPP or PBDTT-SeDPP, appears to have the opposite effect, ultimately causing severe reductions in device performance. To better understand the working mechanism as well as the differing photovoltaic device performance in different ternary BHJ systems, we further characterized the charge transport property and the recombination dynamics.

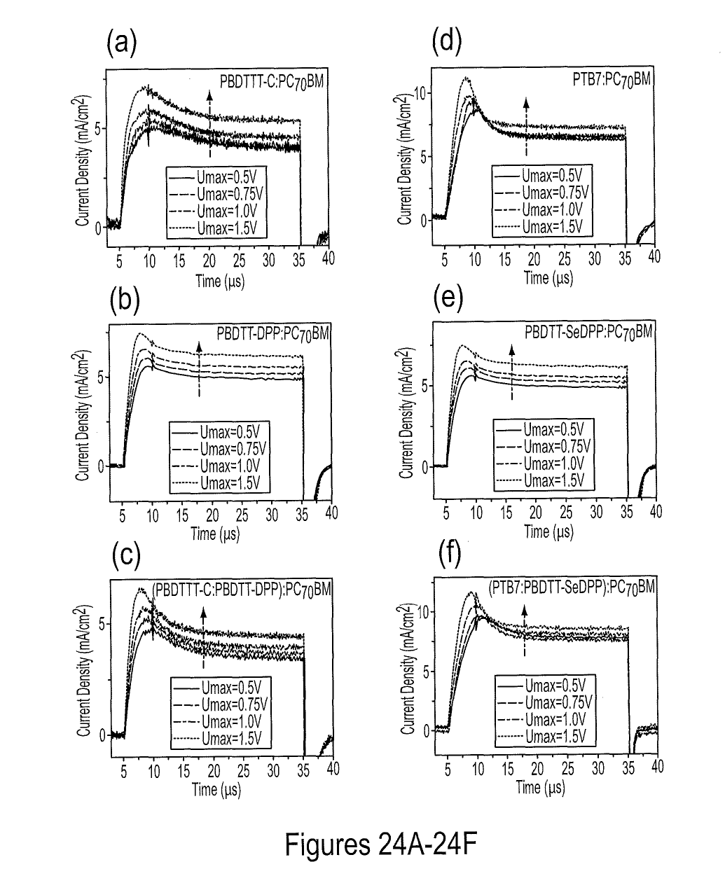

Charge transport is critical to organic photovoltaic device performance, especially in polymer solar cells with multiple donors. Unfavorable interactions between different polymers within the active layer can easily inhibit charge transport capabilities and hence limit device efficiency. FIGS. 24A-E show the electric field dependent CELIV photocurrent transient characteristics of the binary and its corresponding ternary systems. Photo-CELIV transients are shown for PBDTTT-C:PC₇₀BM (FIG. 24A); PBDTT-DPP:PC₇₀BM (FIG. 24B); (PBDTTT-C:PBDTT-DPP):PC₇₀BM (FIG. 24C); PTB7:PC₇₀BM (FIG. 24D); PBDTT-SeDPP:PC₇₀BM (FIG. 24E); and (PTB7:PBDTT-SeDPP):PC₇₀BM (FIG. 24A) with different applied electric fields. All of the ternary BHJ devices have the same blending ratio of 1:1. The effective charge carrier mobility of the organic film with moderate conductivity can be estimated based on the following equation^{30, 31}:

$$μ = \frac{2 {d}^{2}}{3 {At}_{max}^{2} [ 1 + 0.36 \frac{Δ j}{j ( 0 )} ]} if Δ j \leq j ( 0 ) \qquad ( Equation 3 )$$

where μ is the mobility, d is the thickness of the BHJ active layer, tₘₐₓ is the time when the extracted current reaches its maximum value, A is the slope of the extraction voltage ramp, j(0) is the dark capacitive current, and Δj is the transient current peak height, as shown in FIG. 10A.

The mobility value of the effective charge carriers in the (PBDTTT-C:PBDTT-DPP=1:1):PC₇₀BM ternary system was 9.6×10⁻⁵ cm²/V sec, which was comparable to the PBDTT-DPP:PC₇₀BM device's mobility (9.7×10⁻⁵ cm²/V sec), and even slightly higher than the other binary reference PBDTTT-C:PC₇₀BM device's mobility (4.0×10⁻⁵ cm²/V sec). In the other compatible ternary BHJ solar cell system, the (PTB7:PBDTT-SeDPP=1:1):PC₇₀BM ternary system has an effective carrier mobility of 6.5×10⁻⁵ cm²/V sec, comparable to its corresponding binary systems, the PTB7:PC70BM device (5.4×10⁻⁵ cm²/V sec) and the PBDTT-SeDPP:PC70BM device (9.2×10⁻⁵ cm²/V sec). This indicates that the transport property within the structurally compatible ternary BHJ solar cell is not interrupted, and may even be enhanced.

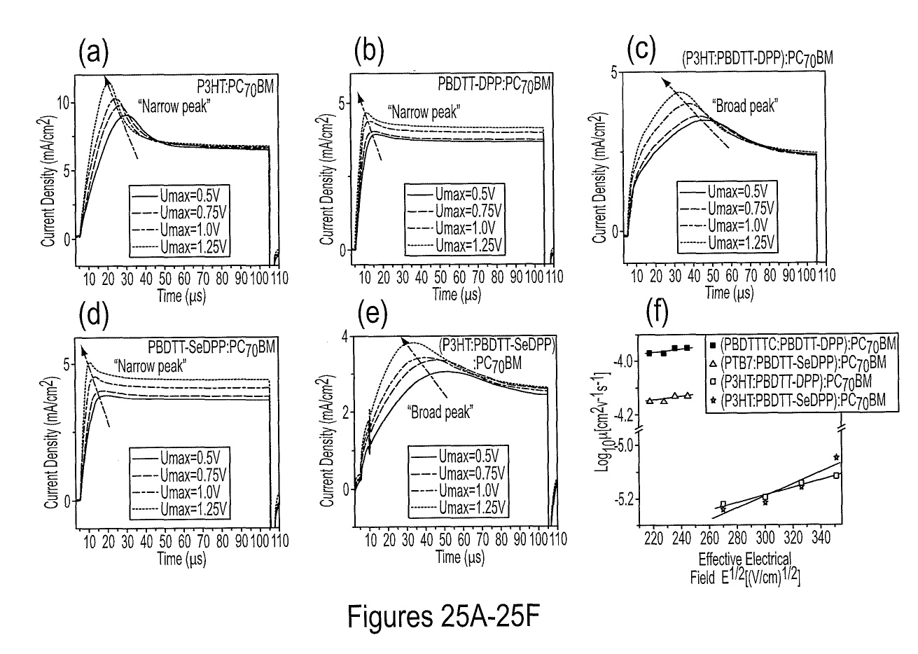

On the other hand, in devices made from the incompatible ternary BHJ system containing P3HT and PBDTT-DPP or PBDTT-SeDPP, a very different CELIV pattern was observed, as shown in FIGS. 25A-25E. Photo-CELIV transients are shown for P3HT:PC70BM (FIG. 25A); PBDTT-DPP:PC₇₀BM (FIG. 25B); (P3HT:PBDTT-DPP):PC₇₀BM (FIG. 25C); PBDTT-SeDPP:PC₇₀BM (FIG. 25D); and (P3HT:PBDTT-SeDPP):PC₇₀BM (FIG. 25E) with different applied electric fields. All of the ternary BHJ devices have the same blending ratio of 1:1. Electric field dependent charge carrier mobility of the compatible and incompatible ternary BHJ solar cell systems. Both (P3HT:PBDTT-DPP):PC₇₀BM and (P3HT:PBDTT-SeDPP):PC₇₀BM ternary systems showed a much broader current transient peak, which implied that the charge transport inside those BHJs was much more dispersive. The tₘₐₓ values of the unfavorable ternary BHJ solar cells were larger. Accordingly, the effective carrier mobility was at least one order lower than that of their corresponding binary references. The electric field dependent carrier mobility was also studied by varying the highest extraction voltage. FIG. 25F shows electric field dependent charge carrier mobility of the compatible and incompatible ternary BHJ solar cell systems. As seen in FIG. 25F, the carrier mobility of the incompatible ternary BHJ devices incorporated with P3HT and low band gap polymers is one order lower than that of the compatible ternary BHJ devices. Besides, they exhibit stronger positive field dependence, which usually indicates an energetically disordered character. The dramatically different charge transport property within different ternary BHJ solar cell systems explains the different fill factors observed from these devices.

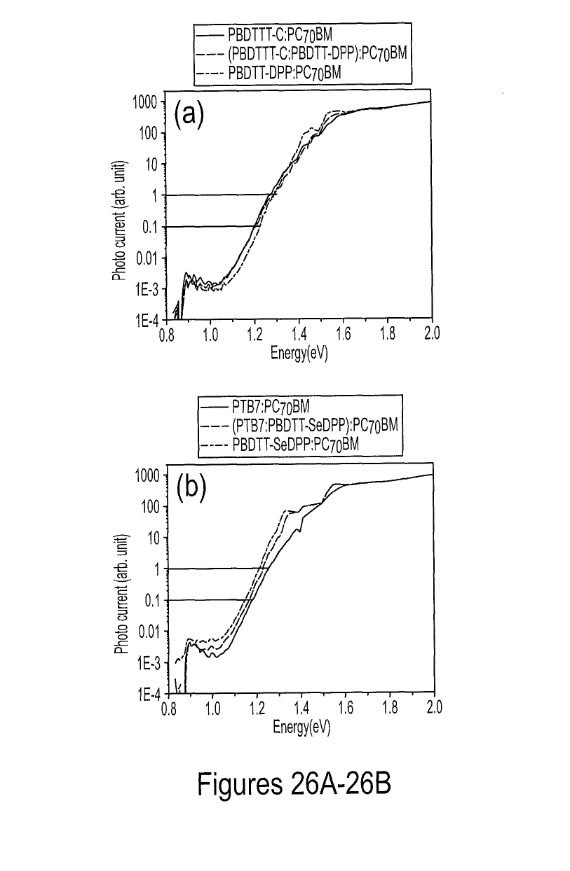

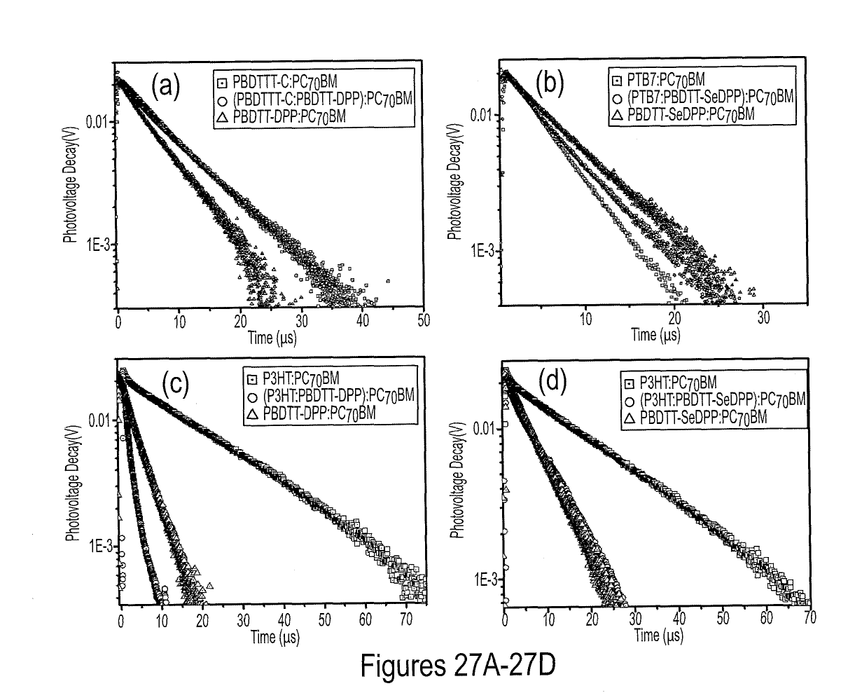

The charge transport study implies that more electronic traps arise if incompatible polymers are blended, and generally those uncomplimentary traps might provide as recombination centers as well, and the open circuit voltage will be limited if the recombination loss is severe enough. The open circuit voltage describes the energetic transfer process from exciton generation to free carrier collection, and is of particular interest for the ternary BHJ solar cells.^{32, 33} It is known that the Voc is determined by the effective band gap of the donor/acceptor blends subtracted by recombination loss.^{34, 35} For the conventional binary BHJ, the effective band gap can be simply defined as the difference between the highest occupied molecular orbital (HOMO) of the donor and the lowest unoccupied molecular orbital (LUMO) of the acceptor,³⁴ however that is no longer practical for the ternary or multiple compounds systems. A better way to define it is through its equivalent charge transfer state, which sets the upper limit of the Voc. The tunable charge transfer state is observed in some of the ternary BHJ solar cell systems.³⁶ In our case, we also find that the charge transfer state of the (PBTDDD-C:PBDTT-DPP):PC₇₀BM and (PTB7:PBDTT-SeDPP):PC70BM ternary systems is roughly in between that of the relative binary systems, but is slightly closer to the reference with lower charge transfer state, measured by the highly sensitive photo spectral response (PSR). FIGS. 26A and 26B show the PSR of the ternary BHJ solar cell systems of a (PDBTTT-C:PBDTT-DPP):PC70BM system (FIG. 26A) and a (PTB7:PBDTT-SeDPP):PC70BM system (FIG. 26B). The Voc difference correlates well with the measured charge transfer state, which suggests that the recombination loss within such systems are around the same level. The recombination dynamics were directly investigated by the transient photo-voltage (TPV), as shown in FIGS. 27A-27D. FIGS. 27A-27D show TPV decay of the ternary BHJ solar cell systems of (PDBTTT-C:PBDTT-DPP):PC₇₀BM (FIG. 27A); (PTB7:PBDTT-SeDPP):PC₇₀BM (FIG. 27B); (P3HT:PBDTT-DPP):PC70BM (FIG. 27C); and (P3HT:PBDTT-SeDPP):PC₇₀BM (FIG. 27D). The measurements were conducted under one-sun light bias. The solar cell is considered as working on the open circuit condition, (connected with a 1M Ω resistor) so the transient photo-voltage decay describes the recombination of the photo-induced carriers.³⁷ FIGS. 27A and 27B indicate that the carrier lifetime of the compatible ternary BHJ solar cells is not reduced compared with their corresponding binary systems, an may even be increased. On the other hand, the carrier lifetime of poorly-performed ternary systems containing P3HT and PBDTT-DPP or PBDTT-SeDPP, is much lower than that of the P3HT:PC₇₀BM device, and is close to or lower than that of the low band gap polymer:PC₇₀BM devices. It is worth mentioning that only the carrier lifetime value itself doesn't necessarily predicate the recombination rate, and the open circuit charge carrier density also matters, which can be determined by charge extraction experiments.³⁸ To summarize, the Voc can be well maintained if compatible polymers are mixed, since negligible additional recombination is introduced.

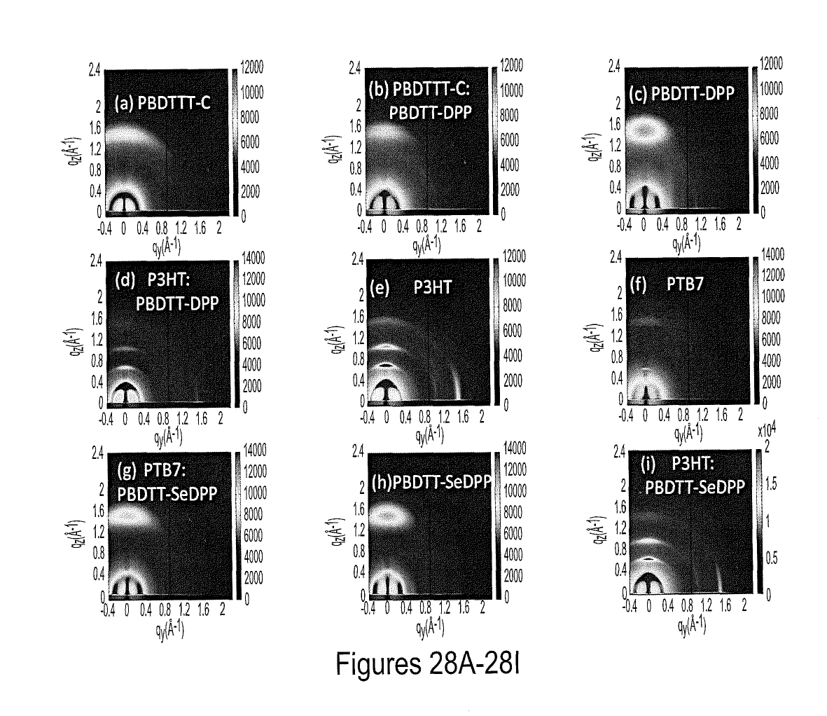

To correlate the electronic properties of the ternary blending and photovoltaic device performance with the structural information, and understand the physical origin on the molecular level, GIWAXS was performed. The 2D GIWAXS patterns for each individual polymer and their blends are shown in FIGS. 28A-28I. GIWAXS patterns are shown for (a) PBDTTT-C (FIG. 28A); PBDTTT-C:PBDTT-DPP blending (FIG. 28B); PBDTT-DPP (FIG. 28C); P3HT:PBDTT-DPP blending (FIG. 28D); P3HT (FIG. 28E); PTB7 (FIG. 28F); PTB7:PBDTT-SeDPP blending (FIG. 28G); PBDTT-SeDPP (FIG. 28H); and P3HT:PBDTT-SeDPP blending (FIG. 28I). All thin film samples were measured on an Si substrate (with naturally formed SiO₂ surface) pre-coated with 30 nm of PEDOT:PSS. Distinct out-of-plane peaks appear in the PBDTTT-C, PBDTT-DPP, PTB7, and PBDTT-SeDPP films, with q_{z}=1.57±0.06 Å, 1.60±0.06 Å⁻¹, 1.61±0.06 Å⁻¹ and 1.60±0.06 Å⁻¹ respectively, which are associated with the π-π stacking distance of 4.0±0.2 Å. This indicates that the π-π stacking direction is perpendicular to the substrate in such films, and thus a “face-on” orientation is preferred. After PBDTTT-C and PBDTT-DPP were blended together, this π-π stacking peak still appears in the 2D GIWAXS pattern with qz=1.58±0.06 Å, which suggests that the preferred molecular orientation with the substrate remains unchanged in the blended film.

The π-π stacking coherence length can also be estimated using the full width at half-maximum (fwhm) of the scattering peaks based on the Scherrer equation^{40, 41}:

L_{π-π}=2(ln 2/π)^{1/2}2π(Δq)⁻¹ (Equation 4)

We found that the coherence length along the π-π stacking direction for PBDTTT-C, PBDTTT-C:PBDTT-DPP blend, and PBDTT-DPP are 15 Å, 19 Å, and 15 Å, respectively, which corresponds to roughly 3˜4 stacked molecules in the pristine polymer films, and slightly increases to 4˜5 stacked molecules in the blending film.

These results indicate a general retention of π-π coherence length (L_{π-π}) after the two “face-on” polymers are mixed, which is a promising sign of their ability to form compact films without disrupting the morphology and stacking structure of the other polymer. Similarly, the distinctive π-π stacking peak is also retained in the PBT7:PBDTT-SeDPP blending film, and the π-π coherence length (L_{π-π}) is 17 Å, comparable to pristine PTB7 (18 Å) and pristine PBDTT-SeDPP (17 Å).

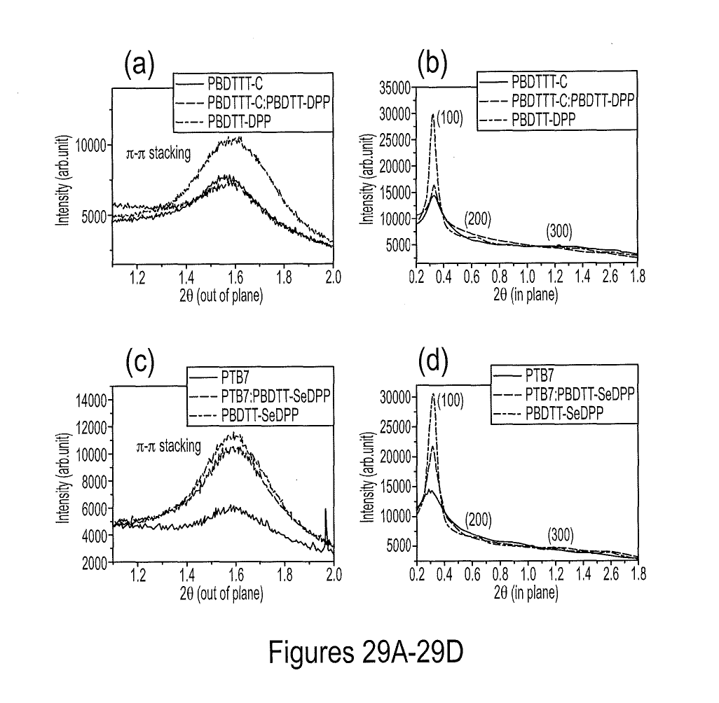

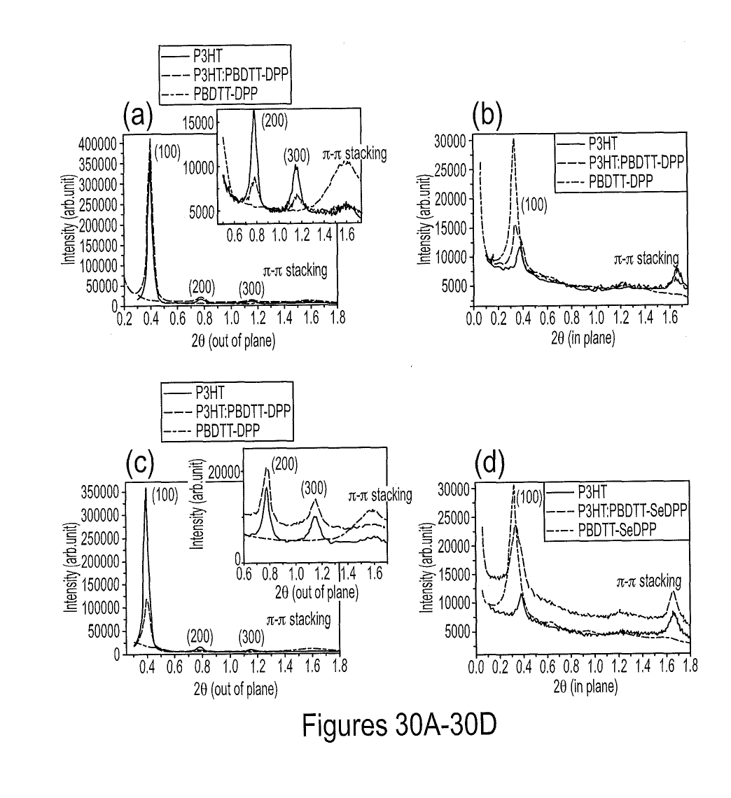

In the P3HT case, the π-π stacking peak in pure P3HT films show up both in plane and out of plane, but more manifestly in the in-plane axis, with q_{y}=1.61±0.01 Å⁻¹ indicating a stronger preference for the “edge-on” orientation. Three distinct peaks arising from the (100), (200), and (300) Bragg diffraction peaks corresponding to periodic P3HT lamellae in the out-of-plane direction were also observed, which have been reported in previous structural studies of P3HT films¹⁷. Unfortunately, when blending the PBDTT-DPP with the P3HT, no scattering peaks corresponding to v-t stacking of both polymers (particularly PBDTT-DPP) were observed in the out-of-plane direction, suggesting that the ordered molecular packing along the vertical direction was significantly suppressed in the mixtures of P3HT and PBDTT-DPP. It is generally believed that the face-on orientation is more favorable for photovoltaic device due to its vertical charge transportation channel. The undermined molecular ordering along the vertical direction inevitably impedes the charge transportation property of the photovoltaic device. Due to the strong crystallinity of P3HT, the in-plane π-π stacking peak is still present in the blending film, however, the π-π stacking coherence length (L_{π-π}) is reduced from 61 Å to 50 Å, corresponding to a reduced number of π-π stacked molecules from ˜15 to ˜12, which implies that the molecular ordering in the in-plane direction is interrupted as well. The GIWAXS pattern of the P3HT and PBDTT-SeDPP demonstrates a similar trend. The GIWAXS scanning curves along each direction are provided in FIGS. 29 and 30. FIGS. 29A-29D show GIWAXS scanning curves for a PBDTTT-C:PBDTT-DPP blending system out of plane (FIG. 29A); a PBDTTT-C:PBDTT-DPP blending system in plane (FIG. 29B); a PTB7:PBDTT-SeDPP blending system out of plane (FIG. 29C); and a PTB7:PBDTT-SeDPP blending system in plane (FIG. 29D). FIGS. 30A-30D show GIWAXS scanning curves for a P3HT:PBDTT-DPP blending system out of plane (FIG. 30A); a P3HT:PBDTT-DPP blending system in plane (FIG. 30B); a P3HT:PBDTT-SeDPP blending system out of plane (FIG. 30C); and a P3HT:PBDTT-SeDPP blending system in plane (FIG. 30D). The measurements indicate that the molecular ordering is well maintained in the compatible polymer mixture, but is greatly disturbed in the incompatible polymer blending. The molecular disorder arising from the mixing of incompatible polymers is very likely one of the key physical origins of the electronic traps and recombination sites, and hence limits the photovoltaic performance of the multiple donor solar cells. The non-conjugated polymer side chain is largely insulating, while the conjugated backbone is conductive. When two polymers with different molecular orientation are mixed, as in the P3HT:PBDTT-DPP blended system, the non-conductive side chain of one polymer is likely to be close to the conductive conjugated backbone of the other polymer. This type of unfavorable molecular pattern becomes “morphological traps”, reducing the crystalline length, disrupting long range charge transport and lowering the charge carrier mobility of the blended film. The scenario of the local molecular disordering is illustrated in FIG. 5.

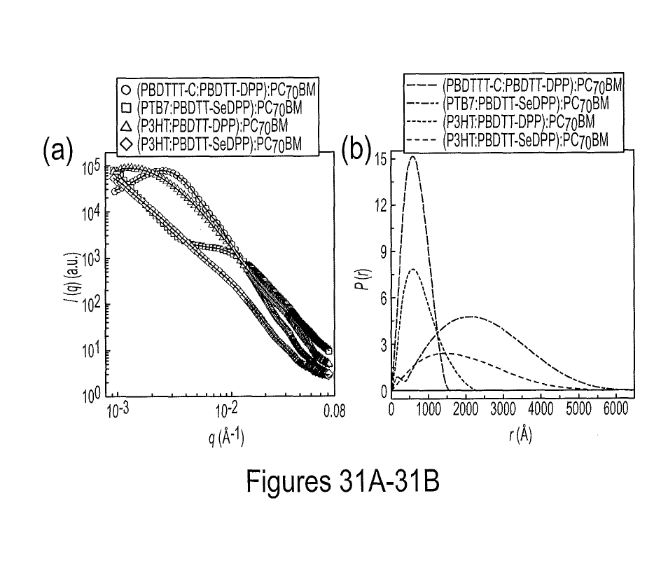

Besides the molecular crystallinity, another important morphological factor that will determine the photovoltaic performance is how the localized molecular crystals and aggregates form phase-separated domains in the BHJ. FIG. 31A show the resonant soft X-ray scattering (RSoXS) profiles (open symbols), and the calculated scattering intensities, I(q), (solid lines) of the compatible and incompatible ternary BHJ films. FIG. 31B show the corresponding pair distance distribution functions (PDDFs), P(r), of the compatible and incompatible ternary BHJ films. (PBDTTT-C:PBDTT-DPP):PC₇₀BM, (P3HT:PBDTT-DPP):PC70BM and (P3HT:PBDTT-SeDPP):PC₇₀BM form similar domain structures at the length scales of hundreds of nanometers. As indicated by the zero crossing of P(r), (P3HT:PBDTT-DPP):PC₇₀BM and (P3HT:PBDTT-SeDPP):PC₇₀BM exhibit much larger domain size than (PBDTTT-C:PBDTT-DPP):PC₇₀BM, which correlates with their unsatisfactory device performance, especially the low Jsc. Interestingly, the best performing (PTB7:PBDTT-SeDPP):PC₇₀BM ternary BHJ device shows hierarchical nanomorphologies at multiple length scales, consistent with the previous observations in PTB7:PC70BM.^{40, 42} A kink in P(r) at the length scales of tens of nanometers indicates that the fine domains are even smaller than the those of the other three blended systems. These compositionally heterogeneous small domain regions exist inside phase-separated domains with a scale of hundreds of nanometers. It has been proposed that these hierarchical nanomorphologies are related to significantly enhanced exciton dissociation, which consequently contributes to the photocurrent.⁴⁰ The retention of such nanostructural characteristics at multiple length scales not only explains the high efficiency of the (PTB7:PBDTT-SeDPP):PC₇₀BM device but also demonstrates that the sophisticated nanomorphology determining the superior device performance can be well maintained in compatible ternary BHJ systems.

The ternary BHJ solar cell represents a more complicated material system, and the underlying working mechanism may vary. There are several possibilities of how the blending donor materials interact with each other. Brabec et al. pointed out possible mechanisms like: 1. the low band gap donor function as an IR-sensitizer; 2. the exciton energy transfers from the wide band gap donor to the low band gap donor; and 3. each donor work independently.²³ These possible working principles could dominate or coexist in one specific ternary system.

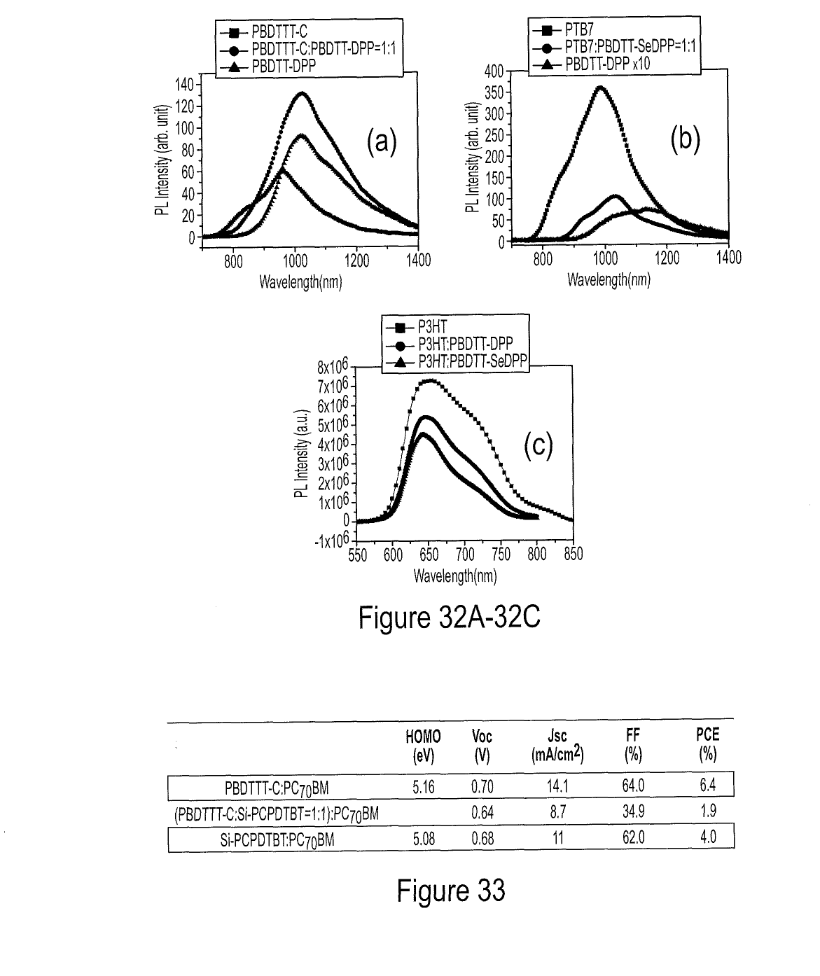

In the successful ternary systems studied in this manuscript, the HOMO of the blending materials are selected to be close to each other. FIG. 32A-32C show photoluminescence spectra for a PBDTTT-C:PBDTT-DPP blending system (FIG. 32A); a PTB7:PBDTT-SeDPP blending system (FIG. 32B); and P3HT:PBDTT-DPP and P3HT:PBDTT-SeDPP blending systems (FIG. 32C). Given the fact that the photoluminescence (PL) spectra of the ternary system is approximately the summation of each material, the polymer donors are most likely to work independently like parallel devices. The nanomorphology of each polymer in the ternary blend system clearly plays a significant role, since they both contribute to the hole transport pathway.

In the incompatible polymer blending cases (e.g. P3HT:PBDTT-DPP and P3HT:PBDTT-SeDPP), we first observed that the PL of P3HT is not effectively quenched by adding low band gap donors, as shown in FIG. 32C. This indicates the exciton energy transfer from P3HT to the low band gap polymer is not the dominating mechanism. Löslein et al. showed that in P3HT and Si-PCPDTBT (or PSDTBT⁴³) ternary system⁴⁴, the low band gap polymer works as an IR-sensitizer and transfers the hole to the P3HT, due to the relatively bigger HOMO level difference in such systems. This scenario may co-exist in the incompatible polymer blending cases (e.g. P3HT:PBDTT-DPP and P3HT:PBDTT-SeDPP). In such cases, the hole transport (independent of whether it is primarily determined by the P3HT, or if both polymers contribute) is interrupted by the blending process, in which the nanomorphology of both P3HT and the low band gap polymer are disrupted, and it provides an explanation for the hindered charge transport and lower device efficiency.

An alternative explanation originating from the HOMO difference is worth discussing. The HOMO difference of P3HT and the low band gap polymers may induce energetic disorder that impedes the charge transport. If this is the dominating mechanism for successful ternary BHJ solar cells, ensuring a small HOMO offset should lead to success. We studied the ternary BHJ cell consisting of PBDTTT-C(HOMO: 5.08 eV) and Si-PCPDTBT (5.16 eV), which have very similar HOMO levels. However, as clearly shown in the table in FIG. 33, the ternary system doesn't give any promising device performance. This indicates that the HOMO offset does not play a dominant role in determining ternary solar cell performance in our case.

Taken together, the GIWAXS and RSoXS results explain on a molecular and domain scale the dramatically different electronic and photovoltaic device performance of the two ternary BHJ systems. The blending of structurally compatible polymers with the identical BDT unit does not introduce significant interference to their molecular stacking preferences, and crystallite size and domain structure are also retained. Therefore, the electronic properties are preserved in the ternary blends; two different molecules can coexist in harmony, and contribute to the improved photovoltaic performance by broadening the absorption range. With this in mind, we can infer that molecules with complementary absorption ranges and good structural compatibility, such as similar crystallinity and molecular orientation, are potential candidates to achieve high performance ternary BHJ solar cells. Structural compatibility may also be linked to polymers with similar molecular groups, such as the shared BDT unit in the backbones of PBDTTT-C and PBDTT-DPP.

In summary, we report the structural, electronic, and photovoltaic characteristics of several ternary BHJ solar cell systems. Two successful ternary BHJ solar cells have been demonstrated, and the most efficient devices achieved 8.7% PCE. By comparing the successful and unsuccessful multiple donor systems, a relationship between device performance and the molecular structure of the donor materials has been established. We conclude that structural compatibility is the key factor for achieving high performance in multiple donor BHJ polymer solar cells. Indications of compatibility between polymers include preferred molecular orientation, crystallite size, domain structure and so on. This work not only proves the feasibility of producing highly efficient BHJ polymer solar cells that incorporate more than one donor material, but also provides guidelines for matching existing materials and designing new ones explicitly for achieving high performance OPVs.

The following materials were used according to an embodiment of the invention. P3HT was purchased from Rieke Metals. PC₇₀BM were purchased from Nano-C. PTB7 and PBDTTT-C were purchased from 1-Material Inc and Solarmer Materials Inc., respectively. These materials were used as received without further purification. PBDTT-DPP and PBDTT-SeDPP were synthesized in-house, according to recipes reported in previous papers^{18, 22}. The polymers used in this project were all from the same batch in order to ensure a fair comparison between experimental and control devices.

Device fabrication and measurement is described according to an embodiment of the invention. Photovoltaic devices were fabricated on indium tin oxide (ITO) coated glass substrates that served as the anode. The ITO substrates were ultrasonically cleaned in detergent, deionized water, acetone, and isopropanol. A layer of 30 nm PEDOT:PSS (poly(3,4-ethylenedioxythiophene):poly(styrene sulfonate)) (Baytron P VPAI 4083, Germany) was spin-coated onto the ITO substrate and was dried in air at 120° C. for 10 minutes. Polymer/PC₇₀BM or Polymer blend/PC₇₀BM were dissolved in 1,2-dichlorobenzene (O-DCB) and were spin-coated on top of the PEDOT layer. Finally, the Ca/Al cathode (100 nm) was vacuum evaporated onto the annealed photoactive layer.

The reference P3HT is described according to an embodiment of the invention. PC70BM solar cells were spin coated at 800 rpm with a 1:1 D/A ratio followed by a “slow growth” method, as reported in the literature⁹. The thickness was approximately 210 nm. For both the (PBDTTT-C:PBDTT-DPP):PC₇₀BM and (PTB7:PBDTT-SeDPP):PC₇₀BM ternary BHJ solar cell systems, the D/A ratio was kept at 1:2, and each was spin cast from (DCB+3% DIO) solutions. The optimized thicknesses for PBDTTT-C:PC₇₀BM, (PBDTTT-C:PBDTT-DPP=1:1):PC70BM and PBDTT-DPP:PC₇₀BM solar cells were 100 nm, 120 nm, and 105 nm, respectively. In the (PTB7:PBDTT-SeDPP):PC₇₀BM ternary BHJ solar cell system, the optimized thicknesses for PTB7:PC₇₀BM, (PTB7:PBDTT-SeDPP=1:1):PC₇₀BM and PBDTT-DPP:PC₇₀BM solar cells were 95 nm, 115 nm, and 100 nm, respectively. For the four-donor BHJ solar cell, the active layer was spin-cast from the combined solution of (PBDTTT-C:PBDTT-DPP=1:1):PC₇₀BM and (PTB7:PBDTT-SeDPP=1:1):PC₇₀BM with a 1:1 vol. ratio, so that the D/A ratio was 1:2, and the device thickness was roughly 120 nm.

The effective area of the devices was 0.1 cm². The current-voltage (J-V) measurements of the photovoltaic devices were conducted using a Keithley 236 Source-Measure unit. A xenon lamp with an AM1.5G filter (NEWPORT) simulated 1 sun conditions, and the light intensity at the sample was 100 mW/cm², calibrated with a Mono-Si photodiode with a KG-5 color filter. The reference diode is traceable to NREL certification. EQE measurements were conducted with an integrated system from EnliTech, Taiwan.

Photo-induced charge carrier extraction in a linearly increasing voltage (Photo-CELIV) measurements are described according to an embodiment of the invention. Photo-CELIV measurements were used to determine the charge carrier mobility in the single and multiple donor BHJ solar cells. The device structure was ITO/PEDOT:PSS/polymer or polymer blend:PC71BM/Ca/Al. A 590 nm dye (Rhodamine Chloride 590) laser pumped by a nitrogen laser (LSI VSL-337ND-S) was used as the excitation source, with pulse energy and pulse width values of 0.03 μJ/cm² and 4 ns, respectively. The triangle voltage pulse was applied by the function generator (Tektronix AFG 3532). The current transient was recorded by a digital oscilloscope (Tektronix DPO 4104). The offset voltage was applied to all the measurements to compensate for the internal electric field. The field dependent mobility was measured by modulating the highest extraction voltage. The effective electric field was determined by E=At/d, where t is the time when current transient perturbation Δj approaches the displacement current j(0), which means that the charge extraction is complete. CELIV is not considered optimal for measuring accurate field dependent mobility since the electric field is varied during measurement. Here, we only focused on the relative comparison of the field dependence.

Transient photovoltage (TPV) measurements are described according to an embodiment of the invention. The device structure was ITO/PEDOT:PSS/Polymer or Polymer Blend:PC₇₁BM/Ca/Al. A 590 nm dye (Rhodamine Chloride 590) laser pumped by a nitrogen laser (LSI VSL-337ND-S) was used as the excitation source, with pulse energy and pulse width values of 0.03 μJ/cm² and 4 ns, respectively. The measurement was conducted under one sun conditions by illuminating the device with a while light LED. The input impedance of the oscilloscope (Tektronix DPO 4104) was 1 MΩ, and the solar cell device was considered as working at the open circuit condition. The charge carrier cannot be extracted but recombined. Therefore, the transient decay can represent the charge carrier lifetime.

For high-sensitivity photo spectral response (PSR) measurements according to an embodiment of the invention, the experimental set up was basically similar as that of the EQE measurement, but with much higher sensitivity.

The incident light was modulated with an optical chopper at 277 Hz, and the photocurrent was first amplified using a 100 K resistor and captured by the lock-in amplifier (Stanford Research SR830). The photocurrent can drop ˜6 orders before reaching the noise level.

Grazing Incidence Wide Angle X-ray Scattering (GIWAXS) measurements were performed at the 8ID-E beamline at the Advanced Photon Source (APS), Argonne National Laboratory using x-rays with a wavelength of λ=1.6868 Å and a beam size of ˜200 μm (h) and 20 μm (v).¹ To make the results comparable to those of OPV devices, the samples for the measurements were prepared on PEDOT:PSS modified Si substrates under the same conditions as those used for fabrication of solar cell devices. A 2-D PILATUS 1M-F detector was used to capture the scattering patterns and was situated at 208.7 mm from the samples. Typical GISAXS patterns were taken at an incidence angle of 0.20°, above the critical angles of polymers:PC70BM blends and below the critical angle of the silicon substrate. Consequently, the entire structure of thin films could be detected. The raw scattering intensity was corrected for solid angle correction, efficiency correction for medium (e.g. air) attenuation and detector sensor absorption, polarization correction, flat field correction for removing artifacts caused by variations in the pixel-to-pixel sensitivity of the detector by use of the GIXSGUI package provided by APS, ANL. In addition, the q_{y} linecut was obtained from a linecut across the reflection beam center, while the q_{z} linecut was achieved by a linecut at q_{y}=0 Å¹ using the reflected beam center as zero the silicon substrate. Consequently, the entire structure of the thin films could be detected. In addition, the q_{y} linecut was obtained from a linecut across the reflection beam center. The background of these linecuts was estimated by fitting an exponential function, and the parameters of the scattering peaks were obtained through best fitting using the Pseudo-Voigt type 1 peak function.

RSoXS transmission measurements were achieved at beamline 11.0.1.2 at the Advanced Light Source (ALS), Lawrence Berkeley National Laboratory.² The elliptically polarized undulator (EPU) source provides high X-ray and full polarization control. The energy of the incident beam can be tuned using a variable-line-space, plane grating monochromator providing soft X-rays in the spectral range from 100 to 1500 eV and the resolving power (E/AE) of ˜4000. The beam size at the sample position was ˜100 μm×100 μm. The RSoXS chamber was operated at high vacuum (˜10⁻⁷ Torr) and controlled by LabVIEW software developed at ALS. RSoXS was taken with an X-ray photon energy of 284.2 eV for the best contrast and sensitivity. A customized designed 4-bounce higher order light suppressor was utilized to suppress higher order light generated from the undulator harmonics and monochromator. The spectral purity of the X-ray photons was higher than 99.99%. Samples for RSoXS measurements were first prepared on a PEDOT:PSS modified Si substrate under the same conditions as those used for fabrication of OPV devices, and then transferred to a 1.5 mm×1.5 mm, 100 nm thick Si₃N₄membrane supported by a 5 mm×5 mm, 200 μm thick Si frame (Norcada Inc.). Single quadrant 2-D scattering patterns were collected on an in-vacuum CCD camera (Princeton Instrument PI-MTE). The scattering patterns were radially averaged and the scattering intensity I(q) in arbitrary units after correcting for background scattering recorded from a blank Si₃N₄ window and normalizing to the incident beam intensity I₀ was plotted against the magnitude of the scattering vector, q=4π sin(θ/2)/2 (where θ is the scattering angle and λ is the wavelength of the soft X-rays), on a log-log scale. The calculation of RSoXS intensities, I(q), and PDDFs, P(r), was performed using the generalized indirect Fourier transformation approach^{45,46} through the GIFT software program in the PCG software package.

### REFERENCES

1. Li, G., Zhu, R., & Yang, Y. Polymer solar cells. Nature Photonics, 6(3), 153-161. (2012).
2. Gunes, S., Neugebauer, H., & Sariciftci, N. S. Conjugated polymer-based organic solar cells. Chemical Reviews-Columbus, 107(4), 1324-1338. (2007).
3. Peumans, P., Yakimov, A., & Forrest, S. R. Small molecular weight organic thin-film photodetectors and solar cells. Journal of Applied Physics, 93(7), 3693-3723. (2003)
4. Halls, J. J. M., Walsh, C. A., Greenham, N. C., Marseglia, E. A., Friend, R. H., Moratti, S. C., & Holmes, A. B. Efficient photodiodes from interpenetrating polymer networks. (1995)
5. Shaheen, S. E., Brabec, C. J., Sariciftci, N. S., Padinger, F., Fromherz, T., & Hummelen, J. C. 2.5% efficient organic plastic solar cells. Applied Physics Letters, 78, 841. (2001)
6. Forrest, S. R., MRS Bull., 30,28 (2005)
7. Clarke, T. M., & Durrant, J. R. Charge photogeneration in organic solar cells. Chemical reviews, 110(11), 6736-6767. (2010)
8. Kniepert, J., Schubert, M., Blakesley, J. C., & Neher, D. Photogeneration and Recombination in P3HT/PCBM Solar Cells Probed by Time-Delayed Collection Field Experiments. The Journal of Physical Chemistry Letters, 2(7), 700-705. (2011)
9. Li, G., Shrotriya, V., Huang, J., Yao, Y., Moriarty, T., Emery, K., & Yang, Y. High-efficiency solution processable polymer photovoltaic cells by self-organization of polymer blends. Nature materials, 4(11), 864-868. (2005)
10. Liang, Y., Xu, Z., Xia, J., Tsai, S. T., Wu, Y., Li, G & Yu, L. For the bright future-bulk heterojunction polymer solar cells with power conversion efficiency of 7.4%. Advanced Materials, 22(20), E135-E138. (2010)
11. Dou, L., You, J., Yang, J., Chen, C. C., He, Y., Murase, S., & Yang, Y. Tandem polymer solar cells featuring a spectrally matched low-bandgap polymer. Nature Photonics, 6(3), 180-185. (2012)
12. Chen, H. Y., Hou, J., Zhang, S., Liang, Y., Yang, G., Yang, Y., & Li, G. Polymer solar cells with enhanced open-circuit voltage and efficiency. Nature Photonics, 3(11), 649-653. (2009)
13. Small, C. E., Chen, S., Subbiah, J., Amb, C. M., Tsang, S. W., Lai, T. H., & So, F. High-efficiency inverted dithienogermole-thienopyrrolodione-based polymer solar cells. Nature Photonics, 6(2), 115-120. (2011)
14. He, Z., Zhong, C., Su, S., Xu, M., Wu, H., & Cao, Y. Enhanced power-conversion efficiency in polymer solar cells using an inverted device structure. Nature Photonics, 6(9), 593-597. (2012)
15. You, J., Dou, L., Yoshimura, K., Kato, T., Ohya, K., Moriarty, T., & Yang, Y. A polymer tandem solar cell with 10.6% power conversion efficiency. Nature communications, 4, 1446. (2013)
16. Green, M. A., Emery, K., Hishikawa, Y., Warta, W., & Dunlop, E. D. Solar cell efficiency tables (version 39). Progress in photovoltaics: research and applications, 20(1), 12-20. (2012)
17. Li, G., Yao, Y., Yang, H., Shrotriya, V., Yang, G., & Yang, Y. “Solvent Annealing” Effect in Polymer Solar Cells Based on Poly (3□hexylthiophene) and Methanofullerenes. Advanced functional materials, 17(10), 1636-1644. (2007)
18. Dou, L., Gao, J., Richard, E., You, J., Chen, C. C., Cha, K. C., & Yang, Y. Systematic investigation of benzodithiophene- and diketopyrrolopyrrole-based low-bandgap polymers designed for single junction and tandem polymer solar cells. Journal of the American Chemical Society, 134(24), 10071-1007. (2012)
19. Liang, Y., & Yu, L. A new class of semiconducting polymers for bulk heterojunction solar cells with exceptionally high performance. Accounts of chemical research, 43(9), 1227-1236. (2010)
20. Hou, J., Chen, H. Y., Zhang, S., Chen, R. I., Yang, Y., Wu, Y., & Li, G. Synthesis of a low band gap polymer and its application in highly efficient polymer solar cells. Journal of the American Chemical Society, 131(43), 15586-15587. (2009)
21. Jankovic, Vladan, et al. Active Layer-Incorporated, Spectrally-Tuned Au/SiO₂ Core/Shell Nanorod-Based Light Trapping for Organic Photovoltaics. ACS nano ASAP (2013).
22. Dou, L., Chang, W. H., Gao, J., Chen, C. C., You, J., & Yang, Y. A Selenium□Substituted Low□Bandgap Polymer with Versatile Photovoltaic Applications. Advanced Materials. 25: 825-831. (2012)

### REFERENCES

### Additional Examples

1. Li, G., Zhu, R., & Yang, Y, Polymer solar cells. Nature Photonics, 6(3), 153-161. (2012).
2. Gunes, S., Neugebauer, H., & Sariciftci, N. S. Conjugated polymer-based organic solar cells. Chemical Reviews-Columbus, 107(4), 1324-1338. (2007).
3. Peumans, P., Yakimov, A., & Forrest, S. R. Small molecular weight organic thin-film photodetectors and solar cells. Journal of Applied Physics, 93(7), 3693-3723. (2003)
4. Halls, J. J. M., Walsh, C. A., Greenham, N. C., Marseglia, E. A., Friend, R. H., Moratti, S. C., & Holmes, A. B. Efficient photodiodes from interpenetrating polymer networks. (1995)
5. Shaheen, S. E., Brabec, C. J., Sariciftci, N. S., Padinger, F., Fromherz, T., & Hummelen, J. C. 2.5% efficient organic plastic solar cells. Applied Physics Letters, 78, 841. (2001)
6. Forrest, S. R., MRS Bull., 30,28 (2005)
7. Clarke, T. M., & Durrant, J. R. Charge photogeneration in organic solar cells. Chemical reviews, 110(11), 6736-6767. (2010)
8. Kniepert, J., Schubert, M., Blakesley, J. C., & Neher, D. Photogeneration and Recombination in P3HT/PCBM Solar Cells Probed by Time-Delayed Collection Field Experiments. The Journal of Physical Chemistry Letters, 2(7), 700-705. (2011)
9. Li, G., Shrotriya, V., Huang, J., Yao, Y., Moriarty, T., Emery, K., & Yang, Y. High-efficiency solution processable polymer photovoltaic cells by self-organization of polymer blends. Nature materials, 4(11), 864-868. (2005)
10. Liang, Y., Xu, Z., Xia, J., Tsai, S. T., Wu, Y., Li, G & Yu, L. For the bright future-bulk heterojunction polymer solar cells with power conversion efficiency of 7.4%. Advanced Materials, 22(20), E135-E138. (2010)
11. Dou, L., You, J., Yang, J., Chen, C. C., He, Y., Murase, S., & Yang, Y. Tandem polymer solar cells featuring a spectrally matched low-bandgap polymer. Nature Photonics, 6(3), 180-185. (2012)
12. Chen, H. Y., Hou, J., Zhang, S., Liang, Y., Yang, G., Yang, Y., & Li, G. Polymer solar cells with enhanced open-circuit voltage and efficiency. Nature Photonics, 3(11), 649-653. (2009)
13. Small, C. E., Chen, S., Subbiah, J., Amb, C. M., Tsang, S. W., Lai, T. H., & So, F. High-efficiency inverted dithienogermole-thienopyrrolodione-based polymer solar cells. Nature Photonics, 6(2), 115-120. (2011)
14. He, Z., Zhong, C., Su, S., Xu, M., Wu, H., & Cao, Y. Enhanced power-conversion efficiency in polymer solar cells using an inverted device structure. Nature Photonics, 6(9), 593-597. (2012)
15. You, J., Dou, L., Yoshimura, K., Kato, T., Ohya, K., Moriarty, T., & Yang, Y. A polymer tandem solar cell with 10.6% power conversion efficiency. Nature communications, 4, 1446. (2013)
16. Green, M. A., Emery, K., Hishikawa, Y., Warta, W., & Dunlop, E. D. Solar cell efficiency tables (version 39). Progress in photovoltaics: research and applications, 20(1), 12-20. (2012)
17. Li, G., Yao, Y., Yang, H., Shrotriya, V., Yang, G., & Yang, Y. “Solvent Annealing” Effect in Polymer Solar Cells Based on Poly (3□hexylthiophene) and Methanofullerenes. Advanced functional materials, 17(10), 1636-1644. (2007)
18. Dou, L., Gao, J., Richard, E., You, J., Chen, C. C., Cha, K. C., & Yang, Y. Systematic investigation of benzodithiophene- and diketopyrrolopyrrole-based low-bandgap polymers designed for single junction and tandem polymer solar cells. Journal of the American Chemical Society, 134(24), 10071-1007. (2012)
19. Liang, Y., & Yu, L. A new class of semiconducting polymers for bulk heterojunction solar cells with exceptionally high performance. Accounts of chemical research, 43(9), 1227-1236. (2010)
20. Hou, J., Chen, H. Y., Zhang, S., Chen, R. I., Yang, Y., Wu, Y., & Li, G. Synthesis of a low band gap polymer and its application in highly efficient polymer solar cells. Journal of the American Chemical Society, 131(43), 15586-15587. (2009)
21. Jankovic, Vladan, et al. Active Layer-Incorporated, Spectrally-Tuned Au/SiO2 Core/Shell Nanorod-Based Light Trapping for Organic Photovoltaics. ACS nano ASAP (2013).
22. Dou, L., Chang, W. H., Gao, J., Chen, C. C., You, J., & Yang, Y. A Selenium□Substituted LowQBandgap Polymer with Versatile Photovoltaic Applications. Advanced Materials. 25: 825-831. (2012)
23. Yang, L., Zhou, H., Price, S. C., & You, W. Parallel-like Bulk Heterojunction Polymer Solar Cells. Journal of the American Chemical Society, 134(12), 5432-5435. (2012)
24. Huang, Y. C., Tsao, C. S., Chuang, C. M., Lee, C. H., Hsu, F. H., Cha, H. C., & Su, W. F. Small- and Wide-Angle X-ray Scattering Characterization of Bulk Heterojunction Polymer Solar Cells with Different Fullerene Derivatives. The Journal of Physical Chemistry C, 116(18), 10238-10244. (2012)
25. Liang, Y. Y. et al. Development of new semiconducting polymers for high performance solar cells. J. Am. Chem. Soc. 131, 56-57. (2009)
26. Liang, Y. Y. et al. Highly efficient solar cell polymers developed via fine tuning of structural and electronic properties. J. Am. Chem. Soc. 131, 7792-7799. (2009)
27. Piliego, C., Holcombe, T. W., Douglas, J. D., Woo, C. H., Beaujuge, P. M., & Frechet, J. M. Synthetic control of structural order in N-alkylthieno [3,4-c]pyrrole-4, 6-dione-based polymers for efficient solar cells. Journal of the American Chemical Society, 132(22), 7595-7597. (2010)
28. Bartelt, J. A., Beiley, Z. M., Hoke, E. T., Mateker, W. R., Douglas, J. D., Collins, B. A., Tumbleston, J. R., Graham, K. R., Amassian, A., Ade, H., Frechet, J. M. J., Toney, M. F. and McGehee, M. D. The Importance of Fullerene Percolation in the Mixed Regions of Polymer-Fullerene Bulk Heterojunction Solar Cells. Adv. Energy Mater., 3: 364-374. doi: 10.1002/aenm.201200637. (2013)
29. Rivnay, J., Steyrleuthner, R., Jimison, L. H., Casadei, A., Chen, Z., Toney, M. F., . . . & Salleo, A. Drastic control of texture in a high performance n-type polymeric semiconductor and implications for charge transport. Macromolecules, 44(13), 5246-5255. (2011)
30. Mozer, A. J., Dennler, G., Sariciftci, N. S., Westerling, M., Pivrikas, A., Osterbacka, R., & Juska, G. Time-dependent mobility and recombination of the photoinduced charge carriers in conjugated polymer/fullerene bulk heterojunction solar cells. Physical Review B, 72(3), 035217. (2005)
31. Mozer, A. J., Sariciftci, N. S., Lutsen, L., Vanderzande, D., Osterbacka, R., Westerling, M., & Juska, G. Charge transport and recombination in bulk heterojunction solar cells studied by the photoinduced charge extraction in linearly increasing voltage technique. Applied Physics Letters, 86(11), 112104-112104. (2005)
32. Tremolet de Villers, B., Tassone, C. J., Tolbert, S. H., & Schwartz, B. J. Improving the reproducibility of P3HT: PCBM solar cells by controlling the PCBM/cathode interface. The Journal of Physical Chemistry C, 113(44), 18978-18982. (2009).
33. Kumar, A., Liao, H. H., & Yang, Y. Hole mobility in optimized organic photovoltaic blend films obtained using extraction current transients. Organic Electronics, 10(8), 1615-1620. (2009).
34. Elumalai, N. K., Yin, L. M., Chellappan, V., Jie, Z., Peining, Z., & Ramakrishna, S. Effect of C60 as an electron buffer layer in polythiophene□methanofullerene based bulk heterojunction solar cells. physica status solidi (a), 209(8), 1592-1597. (2012)
35. Melzer, C., Koop, E. J., Mihailetchi, V. D., & Blom, P. W. Hole transport in poly (phenylene vinylene)/methanofullerene bulk□heterojunction solar cells. Advanced Functional Materials, 14(9), 865-870. (2004).
36. Koster, L. J. A., Mihailetchi, V. D., & Blom, P. W. M. Bimolecular recombination in polymer/fullerene bulk heterojunction solar cells. Applied physics letters, 88(5), 052104-052104. (2006)
37. Chen, W., Xu, T., He, F., Wang, W., Wang, C., Strzalka, J., & Darling, S. B. Hierarchical nanomorphologies promote exciton dissociation in polymer/fullerene bulk heterojunction solar cells. Nano letters, 11(9), 3707-3713. (2011)
38. Rivnay, J., Noriega, R., Kline, R. J., Salleo, A., & Toney, M. F. Quantitative analysis of lattice disorder and crystallite size in organic semiconductor thin films. Physical Review B, 84(4), 045203. (2011).
39. Himmelberger, S., Dacuña, J., Rivnay, J., Jimison, L. H., McCarthy Ward, T., Heeney, M., & Salleo, A. Effects of Confinement on Microstructure and Charge Transport in High Performance Semicrystalline Polymer Semiconductors. Advanced Functional Materials. (2012)
40. Sirringhaus, H., Brown, P. J., Friend, R. H., Nielsen, M. M., Bechgaard, K., Langeveld-Voss, B. M. W., & De Leeuw, D. M. Two-dimensional charge transport in self-organized, high-mobility conjugated polymers. Nature, 401(6754), 685-688. (1999)
41. Vakhshouri, K., & Gomez, E. D. Effect of Crystallization Kinetics on Microstructure and Charge Transport of Polythiophenes. Macromolecular rapid communications, 33(24), 2133-2137. (2012)
42. McNeill, C. R., & Ade, H. Soft X-ray characterisation of organic semiconductor films. Journal of Materials Chemistry C, 1(2), 187-201. (2013)
43. Collins, B. A., Cochran, J. E., Yan, H., Gann, E., Hub, C., Fink, R. & Ade, H. Polarized X-ray scattering reveals non-crystalline orientational ordering in organic films. Nature Materials 11, 536-543, (2012)
44. Koppe, M., Egelhaaf, H. J., Clodic, E., Morana, M., Lüer, L., Troeger, A.,& Brabec, C. J. Charge Carrier Dynamics in a Ternary Bulk Heterojunction System Consisting of P3HT, Fullerene, and a Low Bandgap Polymer. Advanced Energy Materials. doi: 10.1002/aenm.201201076. (2013)
45. Hou, J., Chen, H. Y., Zhang, S., Li, G., & Yang, Y. Synthesis, characterization, and photovoltaic properties of a low band gap polymer based on silole-containing polythiophenes and 2, 1, 3-benzothiadiazole. Journal of the American Chemical Society, 130(48), 16144-16145. (2008)
46. Chen, H. Y., Hou, J., Hayden, A. E., Yang, H., Houk, K. N., & Yang, Y. Silicon Atom Substitution Enhances Interchain Packing in a Thiophene□Based Polymer System. Advanced Materials, 22(3), 371-375. (2010)
47. Khlyabich, P. P., Burkhart, B., & Thompson, B. C. Efficient Ternary Blend Bulk Heterojunction Solar Cells with Tunable Open-Circuit Voltage. Journal of the American Chemical Society, 133(37), 14534-14537. (2011)
48. Khlyabich, P. P., Burkhart, B., & Thompson, B. C. Compositional Dependence of the Open-Circuit Voltage in Ternary Blend Bulk Heterojunction Solar Cells Based on Two Donor Polymers. Journal of the American Chemical Society, 134(22), 9074-9077. (2012)

### REFERENCES

### Further Examples

1. Li, G., Zhu, R., & Yang, Y. Polymer solar cells. Nature Photonics, 6(3), 153-161. (2012).
2. Gunes, S., Neugebauer, H., & Sariciftci, N. S. Conjugated polymer-based organic solar cells. Chemical Reviews-Columbus, 107(4), 1324-1338. (2007).
3. Peumans, P., Yakimov, A., & Forrest, S. R. Small molecular weight organic thin-film photodetectors and solar cells. Journal of Applied Physics, 93(7), 3693-3723. (2003)
4. Halls, J. J. M., Walsh, C. A., Greenham, N. C., Marseglia, E. A., Friend, R. H., Moratti, S. C., & Holmes, A. B. Efficient photodiodes from interpenetrating polymer networks. (1995)
5. Shaheen, S. E., Brabec, C. J., Sariciftci, N. S., Padinger, F., Fromherz, T., & Hummelen, J. C. 2.5% efficient organic plastic solar cells. Applied Physics Letters, 78, 841. (2001)
6. Forrest, S. R., MRS Bull., 30, 28 (2005)
7. Clarke, T. M., & Durrant, J. R. Charge photogeneration in organic solar cells. Chemical reviews, 110(11), 6736-6767. (2010)
8. Kniepert, J., Schubert, M., Blakesley, J. C., & Neher, D. Photogeneration and Recombination in P3HT/PCBM Solar Cells Probed by Time-Delayed Collection Field Experiments. The Journal of Physical Chemistry Letters, 2(7), 700-705. (2011)
9. Li, G., Shrotriya, V., Huang, J., Yao, Y., Moriarty, T., Emery, K., & Yang, Y. High-efficiency solution processable polymer photovoltaic cells by self-organization of polymer blends. Nature materials, 4(11), 864-868. (2005)
10. Liang, Y., Xu, Z., Xia, J., Tsai, S. T., Wu, Y., Li, G & Yu, L. For the bright future—bulk heterojunction polymer solar cells with power conversion efficiency of 7.4%. Advanced Materials, 22(20), E135-E138. (2010)
11. Dou, L., You, J., Yang, J., Chen, C. C., He, Y., Murase, S., & Yang, Y. Tandem polymer solar cells featuring a spectrally matched low-bandgap polymer. Nature Photonics, 6(3), 180-185. (2012)
12. Chen, H. Y., Hou, J., Zhang, S., Liang, Y., Yang, G., Yang, Y., & Li, G. Polymer solar cells with enhanced open-circuit voltage and efficiency. Nature Photonics, 3(11), 649-653. (2009)
13. Small, C. E., Chen, S., Subbiah, J., Amb, C. M., Tsang, S. W., Lai, T. H., & So, F. High-efficiency inverted dithienogermole-thienopyrrolodione-based polymer solar cells. Nature Photonics, 6(2), 115-120. (2011)
14. He, Z., Zhong, C., Su, S., Xu, M., Wu, H., & Cao, Y. Enhanced power-conversion efficiency in polymer solar cells using an inverted device structure. Nature Photonics, 6(9), 593-597. (2012)
15. You, J., Dou, L., Yoshimura, K., Kato, T., Ohya, K., Moriarty, T., & Yang, Y. A polymer tandem solar cell with 10.6% power conversion efficiency. Nature communications, 4, 1446. (2013)
16. Green, M. A., Emery, K., Hishikawa, Y., Warta, W., & Dunlop, E. D. Solar cell efficiency tables (version 39). Progress in photovoltaics: research and applications, 20(1), 12-20. (2012)
17. Li, G., Yao, Y., Yang, H., Shrotriya, V., Yang, G., & Yang, Y. “Solvent Annealing” Effect in Polymer Solar Cells Based on Poly (3□hexylthiophene) and Methanofullerenes. Advanced functional materials, 17(10), 1636-1644. (2007)
18. Dou, L., Gao, J., Richard, E., You, J., Chen, C. C., Cha, K. C., & Yang, Y. Systematic investigation of benzodithiophene- and diketopyrrolopyrrole-based low-bandgap polymers designed for single junction and tandem polymer solar cells. Journal of the American Chemical Society, 134(24), 10071-1007. (2012)
19. Liang, Y., & Yu, L. A new class of semiconducting polymers for bulk heterojunction solar cells with exceptionally high performance. Accounts of chemical research, 43(9), 1227-1236. (2010)
20. Hou, J., Chen, H. Y., Zhang, S., Chen, R. I., Yang, Y., Wu, Y., & Li, G. Synthesis of a low band gap polymer and its application in highly efficient polymer solar cells. Journal of the American Chemical Society, 131(43), 15586-15587. (2009)
21. Jankovic, Vladan, et al. Active layer-incorporated, spectrally tuned Au/SiO2 core/shell nanorod-based light trapping for organic photovoltaics. ACS nano 7.5 (2013): 3815-3822.
22. Dou, L., Chang, W. H., Gao, J., Chen, C. C., You, J., & Yang, Y. A Selenium□Substituted Low□Bandgap Polymer with Versatile Photovoltaic Applications. Advanced Materials. 25: 825-831. (2013)
23. Ameri, T., Khoram, P., Min, J., & Brabec, C. J. Organic ternary solar cells: a review. Advanced Materials, 25(31), 4245-4266. (2013)
24. Huang, Y. C., Tsao, C. S., Chuang, C. M., Lee, C. H., Hsu, F. H., Cha, H. C., & Su, W. F. Small- and Wide-Angle X-ray Scattering Characterization of Bulk Heterojunction Polymer Solar Cells with Different Fullerene Derivatives. The Journal of Physical Chemistry C, 116(18), 10238-10244. (2012)
25. Liang, Y. Y. et al. Development of new semiconducting polymers for high performance solar cells. J. Am. Chem. Soc. 131, 56-57. (2009)
26. Liang, Y. Y. et al. Highly efficient solar cell polymers developed via fine tuning of structural and electronic properties. J. Am. Chem. Soc. 131, 7792-7799. (2009)
27. Piliego, C., Holcombe, T. W., Douglas, J. D., Woo, C. H., Beaujuge, P. M., & Fréchet, J. M. Synthetic control of structural order in N-alkylthieno [3,4-c]pyrrole-4, 6-dione-based polymers for efficient solar cells. Journal of the American Chemical Society, 132(22), 7595-7597. (2010)
28. Bartelt, J. A., Beiley, Z. M., Hoke, E. T., Mateker, W. R., Douglas, J. D., Collins, B. A., Tumbleston, J. R., Graham, K. R., Amassian, A., Ade, H., Fréchet, J. M. J., Toney, M. F. and McGehee, M. D. The Importance of Fullerene Percolation in the Mixed Regions of Polymer-Fullerene Bulk Heterojunction Solar Cells. Adv. Energy Mater., 3: 364-374. doi: 10.1002/aenm.201200637. (2013)
29. Rivnay, J., Steyrleuthner, R., Jimison, L. H., Casadei, A., Chen, Z., Toney, M. F., . . . & Salleo, A. Drastic control of texture in a high performance n-type polymeric semiconductor and implications for charge transport. Macromolecules, 44(13), 5246-5255. (2011)
30. Mozer, A. J., Dennler, G., Sariciftci, N. S., Westerling, M., Pivrikas, A., Österbacka, R., & J\check{u}ska, G. Time-dependent mobility and recombination of the photoinduced charge carriers in conjugated polymer/fullerene bulk heterojunction solar cells. Physical Review B, 72(3), 035217. (2005)
31. Mozer, A. J., Sariciftci, N. S., Lutsen, L., Vanderzande, D., Osterbacka, R., Westerling, M., & Juska, G. Charge transport and recombination in bulk heterojunction solar cells studied by the photoinduced charge extraction in linearly increasing voltage technique. Applied Physics Letters, 86(11), 112104-112104. (2005)
32. Khlyabich, P. P., Burkhart, B., & Thompson, B. C. Efficient Ternary Blend Bulk Heterojunction Solar Cells with Tunable Open-Circuit Voltage. Journal of the American Chemical Society, 133(37), 14534-14537. (2011)
33. Khlyabich, P. P., Burkhart, B., & Thompson, B. C. Compositional Dependence of the Open-Circuit Voltage in Ternary Blend Bulk Heterojunction Solar Cells Based on Two Donor Polymers. Journal of the American Chemical Society, 134(22), 9074-9077. (2012)
34. Maurano, A., Hamilton, R., Shuttle, C. G., Ballantyne, A. M., Nelson, J., O'Regan, B., & Durrant, J. R. Recombination dynamics as a key determinant of open circuit voltage in organic bulk heterojunction solar cells: a comparison of four different donor polymers. Advanced Materials, 22(44), 4987-4992. (2010).
35. Vandewal, K., Tvingstedt, K., Gadisa, A., Inganais, O., & Manca, J. V. On the origin of the open-circuit voltage of polymer-fullerene solar cells. Nature materials, 8(11), 904-909. (2009).
36. Street, R. A., Davies, D., Khlyabich, P. P., Burkhart, B., and Thompson, B. C. Origin of the Tunable Open-Circuit Voltage in Ternary Blend Bulk Heterojunction Organic Solar Cells. Journal of the American Chemical Society, 135(3), 986-989. (2013).
37. Shuttle, C. G., O'Regan, B., Ballantyne, A. M., Nelson, J., Bradley, D. D. C., De Mello, J., & Durrant, J. R. Experimental determination of the rate law for charge carrier decay in a polythiophene: Fullerene solar cell. Applied Physics Letters, 92(9), 093311-093311. (2008)
38. Shuttle, C. G., Maurano, A., Hamilton, R., ORegan, B., De Mello, J. C., & Durrant, J. R. Charge extraction analysis of charge carrier densities in a polythiophene/fullerene solar cell: Analysis of the origin of the device dark current. Applied Physics Letters, 93(18), 183501-183501. (2008).
39. Shuttle, C. G., Hamilton, R., O'Regan, B. C., Nelson, J. A., & Durrant, J. R. Charge-density-based analysis of the current-voltage response of polythiophene/fullerene photovoltaic devices. Proceedings of the National Academy of Sciences, 107(38), 16448-16452. (2010).
40. Chen, W., Xu, T., He, F., Wang, W., Wang, C., Strzalka, J., & Darling, S. B. Hierarchical nanomorphologies promote exciton dissociation in polymer/fullerene bulk heterojunction solar cells. Nano letters, 11(9), 3707-3713. (2011)
41. Rivnay, J., Noriega, R., Kline, R. J., Salleo, A., & Toney, M. F. Quantitative analysis of lattice disorder and crystallite size in organic semiconductor thin films. Physical Review B, 84(4), 045203. (2011).
42. Chen, W., Nikiforov, M. P., Darling, S. B. Morphology characterization in organic and hybrid solar cells. Energy Environ. Sci. 5, 8045-8074 (2012).
43. Hou, Jianhui, et al. “Synthesis, characterization, and photovoltaic properties of a low band gap polymer based on silole-containing polythiophenes and 2, 1, 3-benzothiadiazole.” Journal of the American Chemical Society 130.48 (2008): 16144-16145.
44. Löslein, Heiko, et al. Transient Absorption Spectroscopy Studies on Polythiophene-Fullerene Bulk Heterojunction Organic Blend Films Sensitized with a Low-Bandgap Polymer. Macromolecular rapid communications 34.13 (2013): 1090-1097.
45. Brunner-Popela, J., Glatter, O. Small-Angle Scattering of Interacting Particles. I. Basic Principles of a Global Evaluation Technique. J. Appl. Crystallogr. 30, 431-442, (1997).
46. Weyerich, B., Brunner-Popela, J. Glatter, O. Small-angle scattering of interacting particles. II. Generalized indirect Fourier transformation under consideration of the effective structure factor for polydisperse systems. J. Appl. Crystallogr. 32, 197-209, (1999).

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

1. An organic photovoltaic device, comprising:
a first electrode;
a second electrode proximate said first electrode with a space reserved therebetween; and
a bulk heterojunction active layer arranged between and in electrical connection with said first and second electrodes,
wherein said bulk heterojunction active layer comprises a blend of at least one of a plurality of organic electron donor materials and a plurality of electron acceptor materials,
wherein said plurality of organic electron donor materials have different photon absorption characteristics so as to provide an enhanced photon absorption bandwidth, and
wherein said at least one of said plurality of organic electron donor materials and plurality of electron acceptor materials are structurally compatible so as to provide enhanced operation.

2. An organic photovoltaic device according to claim 1, wherein said at least one of a plurality of organic electron donor materials and a plurality of electron acceptor materials comprises organic small molecules.

3. An organic photovoltaic device according to claim 1, wherein said at least one of a plurality of organic electron donor materials and a plurality of electron acceptor materials comprises an organic polymer.

4. An organic photovoltaic device according to claim 1, wherein said at least one of said plurality of organic electron donor materials and plurality of electron acceptor materials are structurally compatible resulting from molecular alignment.

5. An organic photovoltaic device according to claim 1, wherein said bulk heterojunction active layer is a blend comprising PDBTTT-C and PBDTT-DPP.

6. An organic photovoltaic device according to claim 1, wherein said bulk heterojunction active layer is a blend comprising PTB7 and PBDTT-SeDPP.

7. An organic photovoltaic device according to claim 1, wherein said bulk heterojunction active layer is a blend comprising PBDTTT-C, PBDTT-DPP, PTB7, and PBDTT-SeDPP.

8. An organic photovoltaic device according to claim 1, wherein said bulk heterojunction active layer comprises a blend of a plurality of organic electron donor materials.

9. An organic photovoltaic device according to claim 1, wherein said plurality of organic electron donor materials are selected from the group of organic electron donor materials consisting of PBDTTT-C, PBDTT-DPP, PTB7, PBDTT-SeDPP, PCE10, SPV1 and polymers that have a backbone corresponding to any one of the polymers thereof.

10. An organic photovoltaic device according to claim 8, wherein said plurality of organic electron donor materials consist essentially of PDBTTT-C and PBDTT-DPP.

11. An organic photovoltaic device according to claim 8, wherein said plurality of organic electron donor materials consist essentially of PTB7 and PBDTT-SeDPP.

12. An organic photovoltaic device according to claim 8, wherein said plurality of organic electron donor materials consist essentially of PBDTTT-C, PBDTT-DPP, PTB7, and PBDTT-SeDPP.

13. An organic photovoltaic device according to claim 1, wherein said bulk heterojunction active layer comprises a blend of a plurality of organic electron acceptor materials.

14. An organic photovoltaic device according to claim 13, wherein said plurality of electron acceptor materials are selected from the group of electron acceptor materials consisting of P(NDI2OD-T2), PNDIT, PNDIS-HD, PNDTI-BT-DT, PPDI2T, PPDIC, PPDIDTT, YF25, NIDCS-HO, NIBT, Bis-PDI-T-MO, SDIPBI, PDI-2DTT and PDI.

15. A method of producing a composition for a bulk heterojunction active layer of an organic photovoltaic device, comprising:
selecting a first organic electron donor material;
selecting a first electron acceptor material;
selecting at least one of a second organic electron donor material that is structurally compatible with said first organic electron donor material or a second electron acceptor material that is structurally compatible with said first electron acceptor material; and
blending all materials selected to provide said composition.

16. A method of producing a composition for a bulk heterojunction active layer of an organic photovoltaic device according to claim 15, further comprising selecting at least one of a plurality of organic electron donor materials or a plurality of organic electron acceptor materials prior to said blending all materials selected to be included in said blending.

17. A method of producing a composition for a bulk heterojunction active layer of an organic photovoltaic device according to claim 16, wherein at least one material selected comprises an organic small molecule material.

18. A method of producing a composition for a bulk heterojunction active layer of an organic photovoltaic device according to claim 16, wherein at least one material selected comprises an organic polymer material.

19. A method of producing a composition for a bulk heterojunction active layer of an organic photovoltaic device according to claim 16, wherein said structural compatible is molecular alignment.

20. A method of producing a composition for a bulk heterojunction active layer of an organic photovoltaic device according to claim 15, wherein said first organic electron donor is PDBTTT-C and said second organic electron donor material is PBDTT-DPP.

21. A method of producing a composition for a bulk heterojunction active layer of an organic photovoltaic device according to claim 15, wherein said first organic electron donor is PTB7 and said second organic electron donor material is PBDTT-SeDPP.

22. A method of producing a composition for a bulk heterojunction active layer of an organic photovoltaic device according to claim 16, wherein said selecting at least one of a plurality of organic electron donor materials or a plurality of organic electron acceptor materials comprises selecting PBDTTT-C, PBDTT-DPP, PTB7, and PBDTT-SeDPP.

23. A method of producing a composition for a bulk heterojunction active layer of an organic photovoltaic device according to claim 16, wherein said selecting at least one of a plurality of organic electron donor materials or a plurality of organic electron acceptor materials comprises selecting at least two organic donor materials from the group consisting of PBDTTT-C, PBDTT-DPP, PTB7, PBDTT-SeDPP, PCE10, SPV1 and polymers that have a backbone corresponding to any one of the polymers thereof.

24. A method of producing a composition for a bulk heterojunction active layer of an organic photovoltaic device according to claim 16, wherein said selecting at least one of a plurality of organic electron donor materials or a plurality of organic electron acceptor materials comprises selecting at least two organic electron acceptor materials from the group consisting of P(NDI2OD-T2), PNDIT, PNDIS-HD, PNDTI-BT-DT, PPDI2T, PPDIC, PPDIDTT, YF25, NIDCS-HO, NIBT, Bis-PDI-T-MO, SDIPBI, PDI-2DTT and PDI.
